(19) United States
(12) Patent Application Publication
(10) Pub. No.: US 2026/0322078 A1
(43) Pub. Date: Oct. 15, 2026

(54) SYSTEMS AND METHODS FOR PLASMONIC LASERS

(71) Applicant: The General Hospital Corporation, Boston, MA (US)

(72) Inventors: Seok-Hyun Yun, Boston, MA (US); Sangyeon Cho, Boston, MA (US)

(21) Appl. No.: 19/481,085

(22) PCT Filed: May 3, 2024
(86) PCT No.: PCT/US2024/027811

§ 371 Date: Nov. 3, 2025

Related U.S. Application Data
(60) Provisional application No. 63/499,897, filed on May 3, 2023.

(51) Int. Cl. H01S 5/30; H01S 5/04

(52) U.S. Cl. CPC H01S 5/3013; H01S 5/041; H01S 5/3018

(57) ABSTRACT

Laser particles and apparatus for generating plasmonic stimulated emission are provided, which particles include a semiconductor particle configured to provide a gain; and a metal layer disposed on at least one surface of the semiconductor particle, the metal layer configured to provide plasmons, wherein a size of the laser particle is less than 3 μm along its longest dimension.

### CROSS-REFERENCE TO RELATED APPLICATIONS

This application claims the benefit of and priority to U.S. Provisional Patent Application No. 63/499,897, filed on May 3, 2023, entitled “Plasmonic Laser Particles,” the entire contents of which are herein incorporated by reference for all purposes.

### STATEMENT REGARDING FEDERALLY SPONSORED RESEARCH OR DEVELOPMENT

This invention was made with government support under grant numbers EB033155 and EB034687 awarded by the National Institutes of Health. The government has certain rights in the invention.

### TECHNICAL FIELD

This disclosure relates to the field of lasers, and more particularly to systems and methods for optically-pumped narrowband stimulated laser emission using micro- and nano-sized particles.

### BACKGROUND

Plasmonics has been considered as one way to make miniaturized lasers on the nanoscale. Surface plasmon (SP) waves can be confined into sub-diffraction volume and amplified to generate laser light if the supplied optical gain is large enough to overcome the loss. Plasmonic lasers exhibit different scaling laws in the threshold-device size relationship compared to the all-dielectric lasers due to strong light-matter interaction in the metallic cavity.

A number of comparative examples of plasmonic lasers have been demonstrated to date. These include metal substrate-insulator-semiconductor (MIS) architectures, metal deposited structure architectures, and surface plasmonic amplification of stimulated emission of radiation (“spaser”) architectures. In these comparative examples, either the laser devices use bulk planar substrates and as such are not considered or known as particles, or the devices exhibit a low quality factor (Q) due to a small size cavity and relatively low optical gain. In the comparative examples, it is not possible to achieve lasing from single plasmonic particles.

Additionally, various comparative examples of metallic nanoparticles have been studied, which when illuminated by light, are capable of emitting luminescence or fluorescence. In all these cases, the output emission is predominantly provided by spontaneous emission, not stimulated emission that is based on strong optical amplification compensating the large optical attenuation in the nanoscale, high loss nanostructures. Due to low intrinsic Q-factors, the emission linewidth is typically wider than 1/20-th (5%) of the center wavelength of the spectrum.

Particle lasers or laser particles have received interest for their applications to multiplexed barcoding of cells or other microscopic objects. These applications require particles, and the comparative plasmonic lasers are not suited due to the large sizes of substrates. Furthermore, the comparative plasmonic lasers on substrates use optically thick metal layers. It is difficult to pump the semiconductors through optically thick metal layers and also to detect emission from semiconductors through the metal layers. Metal-coated micro- and nanostructures have been demonstrated for various specific purposes, including non-blinking quantum dots, electrocatalysis, hot electron conversion, and reduced photobleaching of fluorescent dyes. However, effective recipes for metal-coated semiconductor structures for miniaturized plasmonic laser particles and spaser particles have not been developed.

### SUMMARY

The present disclosure addresses these and other needs by providing systems and methods for micro- and nano-sized particles that are capable of generating narrowband stimulated laser emission when they receive optical pumping. These laser-emitting particles are comprised of semiconductor and metal materials and use plasmonic effects. This disclosure describes the design, principle, and fabrication of the plasmonic laser particles and optical systems for operating the particles.

According to one aspect of the present disclosure, a laser particle for generating plasmonic stimulated emission is provided. The laser particle comprises a semiconductor particle configured to provide a gain; and a metal layer disposed on at least one surface of the semiconductor particle, the metal layer configured to provide plasmons, wherein a size of the laser particle is less than 3 μm along its longest dimension.

According to another aspect of the present disclosure, an apparatus for generating plasmonic stimulated emission is provided. The apparatus comprises a laser particle comprising a semiconductor particle and a metal layer disposed on at least one surface of the semiconductor particle; a pump source configured to provide electromagnetic energy to the laser particle to excite plasmonic modes; and a photodetector configured to detect the plasmonic stimulated emission.

According to another aspect of the present disclosure, a method for generating plasmonic stimulated emission is provided. The method comprises providing a laser particle, the laser particle comprising a semiconductor particle and a metal layer disposed on at least one surface of the semiconductor particle; delivering an electromagnetic energy to the laser particle to excite plasmonic nodes; and detecting the plasmonic stimulated emission.

### BRIEF DESCRIPTION OF THE DRAWINGS

Some embodiments of the disclosure are described herein with reference to the accompanying figures. The description, together with the figures, makes apparent to a person having ordinary skill in the art how some embodiments of the disclosure may be practiced. The figures are for the purpose of illustrative discussion and no attempt is made to show structural details of an example in more detail than is necessary for a fundamental understanding of the teachings of the disclosures. In the drawings:

FIG. 1A illustrates a substrate-based plasmonic laser device, according to a comparative example.

FIG. 1B illustrates a substrate-based plasmonic laser device, according to a comparative example.

FIG. 1C illustrates a substrate-based plasmonic laser device, according to a comparative example.

FIG. 2A illustrates a nanoparticle for spontaneous emission, according to a comparative example.

FIG. 2B illustrates a nanoparticle for spontaneous emission, according to a comparative example.

FIG. 2C illustrates a nanoparticle for spontaneous emission, according to a comparative example.

FIG. 2D illustrates a nanoparticle for spontaneous emission, according to a comparative example.

FIG. 3A illustrates an example of a plasmonic laser particle, according to various aspects of the present disclosure.

FIG. 3B illustrates an example of a plasmonic laser particle, according to various aspects of the present disclosure.

FIG. 3C illustrates an example of a plasmonic laser particle, according to various aspects of the present disclosure.

FIG. 4 illustrates examples of surface coverages of a metal coating, according to various aspects of the present disclosure.

FIG. 5 illustrates a schematic of optical pumping of a plasmonic laser (spaser) particle above a lasing threshold and stimulated emission of narrowband spectrum from the particle.

FIG. 6 illustrates a schematic of a microscopic readout setup, according to various aspects of the present disclosure.

FIG. 7 illustrates representative data for plasmonic laser particles, according to various aspects of the present disclosure.

FIG. 8 illustrates evidence of lasing, according to various aspects of the present disclosure.

FIG. 9 illustrates a time-resolved photoluminescence decay curve, according to various aspects of the present disclosure.

FIG. 10 illustrates characteristics of plasmonic modes for representative devices, according to various aspects of the present disclosure.

FIG. 11 illustrates Purcell factors of various modes, according to various aspects of the present disclosure.

FIG. 12 illustrates schematics of plasmonic lasers, according to various aspects of the present disclosure.

FIG. 13 illustrates a demonstration of a plasmonic laser device, according to various aspects of the present disclosure.

FIG. 14 illustrates calculated group index and Purcell factors, according to various aspects of the present disclosure.

FIG. 15 illustrates pumping efficiency at various wavelengths, according to various aspects of the present disclosure.

FIG. 16 illustrates transmission electron micrographs (TEMs) of laser particles, according to various aspects of the present disclosure.

FIG. 17 illustrates TEMs of laser particles, according to various aspects of the present disclosure.

FIG. 18 illustrates the coupling of plasmonic and semiconductor dipolar modes.

FIG. 19 illustrates mode properties of metal-semiconductor nanoparticles.

FIG. 20 illustrates size and thickness tuning of semiconductor particles, according to various aspects of the present disclosure.

FIG. 21 illustrates characteristics of semiconductor-on-gold nanodevices, according to various aspects of the present disclosure.

FIG. 22 illustrates example characteristics of half-wave dipolar lasers, according to various aspects of the present disclosure.

FIG. 23 illustrates example characteristics of higher-order mode devices, according to various aspects of the present disclosure.

FIG. 24 illustrates an example semiconductor laser model, according to various aspects of the present disclosure.

FIG. 25 illustrates an example semiconductor laser model, according to various aspects of the present disclosure.

FIG. 26 illustrates example plasmonic laser particles and intracellular lasing, according to various aspects of the present disclosure.

FIG. 27 illustrates laser simulation and experimental results, according to various aspects of the present disclosure.

FIG. 28 illustrates an example structure of metal-semiconductor particles, according to various aspects of the present disclosure.

FIG. 29 illustrates emission spectra of isolated plasmonic LPs, according to various aspects of the present disclosure.

FIG. 30 illustrates a comparison of device volume and mode order for several example devices.

FIG. 31 illustrates the synthesis of gold-coated perovskite particles, according to various aspects of the present disclosure.

FIG. 32 illustrates optical characteristics of gold-coated perovskite particles, according to various aspects of the present disclosure.

FIG. 33 illustrates the functionalization and biological application of gold-coated perovskite particles, according to various aspects of the present disclosure.

FIG. 34 illustrates the synthesis of silver-coated perovskite particles, according to various aspects of the present disclosure.

FIG. 35 illustrates the structure of metal-coated perovskite particles, according to various aspects of the present disclosure.

FIG. 36 illustrates the effects of gold-shell thickness, according to various aspects of the present disclosure.

FIG. 37 illustrates properties of a gold-coated perovskite particle, according to various aspects of the present disclosure.

FIG. 38 illustrates the sensitivity of lasing devices to their external environment, according to various aspects of the present disclosure.

FIG. 39 illustrates the example of plasmonic laser particles partially coated with metal, featuring (a) a tuning fork shape and (b) a bell shape, according to various aspects of the present disclosure.

FIG. 40 illustrates the characteristics of plasmonic modes for semiconductor particles partially coated with metal, featuring (a) a tuning fork shape and (b) a bell shape, according to various aspects of the present disclosure.

FIG. 41 illustrates the characteristics of low-order plasmonic modes of another semiconductor particles partially coated with metal, according to various aspects of the present disclosure.

FIG. 42 illustrates the fabrication process of partially metal-coated InP particles, according to various aspects of the present disclosure.

FIG. 43 illustrates scanning electron micrographs (SEMs) of fabricated partially metal-coated InP particles, according to various aspects of the present disclosure.

FIG. 44 illustrates the optical characteristics of fabricated partially metal-coated InP particles, according to various aspects of the present disclosure.

### DETAILED DESCRIPTION

In the following detailed description, reference is made to the accompanying drawings in which specific examples are shown by way of illustration. These examples are described in sufficient detail to enable those of ordinary skill in the art to practice the disclosure. It should be understood, however, that the detailed description and the specific examples, while indicating examples of embodiments of the disclosure, are given by way of illustration only and not by way of limitation. From this disclosure, various substitutions, modifications, additions rearrangements, or combinations thereof within the scope of the disclosure may be made and will become apparent to those of ordinary skill in the art.

Unless otherwise indicated, the various features illustrated in the drawings may not be drawn to scale. The illustrations presented herein are not necessarily intended to be actual views of any particular method, device, or system, but are merely idealized representations that are employed to describe various embodiments of the disclosure. Accordingly, the dimensions of the various features as illustrated may be arbitrarily expanded or reduced for clarity. In addition, some of the drawings may be simplified for clarity. Thus, the drawings may not depict all of the components of a given apparatus (e.g., device) or method. In addition, like reference numerals may be used to denote like features throughout the specification and figures.

It should be understood that any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements.

Unless otherwise specified or indicated by context, the terms “a,” “an,” and “the” mean “one or more.” As used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “only one of,” or “exactly one of.” For example, a list of “only one of A, B, or C” indicates options of: A, but not B and C; B, but not A and C; and C, but not A and B. In contrast, a list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more A, one or more B, and one or more C. Similarly, a list preceded by “a plurality of” (and variations thereon) and including “or” to separate listed elements indicates options of one or more of each of multiple of the listed elements. For example, the phrases “a plurality of A, B, or C” and “two or more of A, B, or C” indicate options of: one or more A and one or more B; one or more B and one or more C; one or more A and one or more C; and one or more A, one or more B, and one or more C.

As used herein, “about,” “approximately,” “substantially,” and “significantly” will be understood by persons of ordinary skill in the art and will vary to some extent on the context in which they are used. If there are uses of these terms which are not clear to persons of ordinary skill in the art given the context in which they are used, “about” and “approximately” will mean plus or minus ≤10% of the particular term and “substantially” and “significantly” will mean plus or minus >10% of the particular term.

As used herein, the terms “include” and “including” have the same meaning as the terms “comprise” and “comprising” in that these latter terms are “open” transitional terms that do not limit claims only to the recited elements succeeding these transitional terms. The term “consisting of,” while encompassed by the term “comprising,” should be interpreted as a “closed” transitional term that limits claims only to the recited elements succeeding this transitional term. The term “consisting essentially of,” while encompassed by the term “comprising,” should be interpreted as a “partially closed” transitional term which permits additional elements succeeding this transitional term, but only if those additional elements do not materially affect the basic and novel characteristics of the claim.

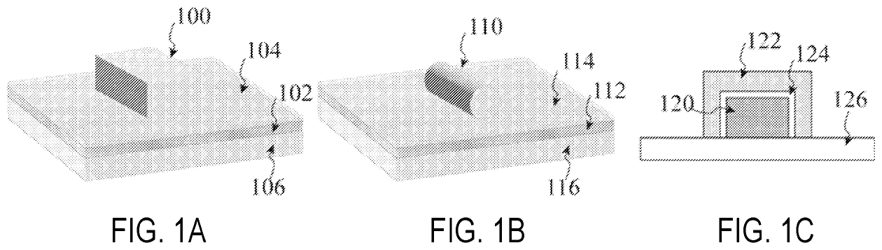

As noted above, comparative examples of plasmonic lasers have been demonstrated to date. FIGS. 1A-1C illustrate three representative comparative structures. FIG. 1A shows a semiconductor gain material 100 placed on top of an insulator layer 104 and a metal layer 102 that is deposited on a glass or crystal substrate 106. This structure is known as the MIS structure. FIG. 1B shows another comparative device, comprising a rod-type semiconductor 110, placed on top of metallic layer 112 in a substrate 116. Typically, an insulating oxide layer 114 is also deposited between the semiconductor 110 and metal 112. In another structure, as illustrated in FIG. 1C, a semiconductor gain medium 120 placed on an optically transparent dielectric substrate 126 is encapsulated with an insulating layer 124 and an optically thick metal layer 122. This is a “metal deposited structure.” In all of these cases, the laser devices use bulk planar substrates, and as such they are not considered or known as particles.

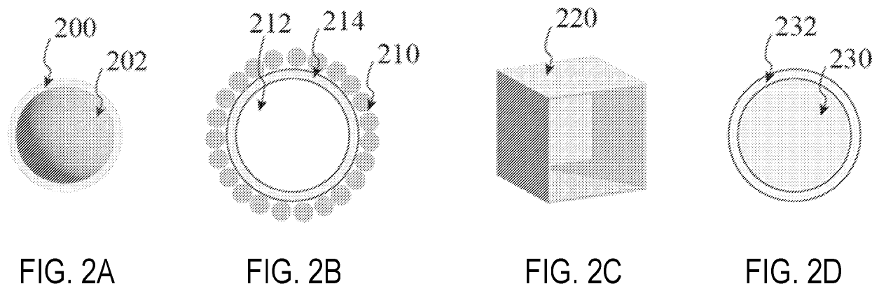

As further noted above, spasers have been investigated as another comparative type of plasmonic lasing. They have a form of nanoparticles. For example, FIG. 2A shows a metallic nanoparticle core 202, which typically has a diameter of <100 nm, that is coated with a dielectric matrix 200 containing fluorescent dye dopants, known as a “metal core-fluorescent shell” structure. Narrowband stimulated emission from these nanoparticles has been reported, although it is believed that the lasing was due to a collective action of many plasmonic particles, and lasing from a single plasmonic nanoparticle remains elusive. A low Q-factor of the small size cavity and relatively low optical gain provided by fluorescent dyes are among the reasons why lasing is not possible from such single plasmonic nanoparticles.

Additionally, various metallic nanoparticles have been studied, which when illuminated by light, are capable of emitting luminescence or fluorescence. Such particles include dielectric core 212, coated with silver shell 214 and semiconductor quantum dots 210, as illustrated in FIG. 2B. FIG. 2C shows hollow gold nano-cubes 220 containing dye molecules. FIG. 2D shows a silver sphere 230 coated with fluorescent materials 232. The emission linewidth is typically given by either the linewidth of fluorescent material incorporated in the nanoparticles or the bandwidth of plasmonic resonance-enhanced scattering by the metallic nanostructures. In all these cases, the output emission is predominantly provided by spontaneous emission, not stimulated emission that is based on strong optical amplification compensating the large optical attenuation in the nanoscale, high loss nanostructures. Due to low intrinsic Q-factors, the emission linewidth is typically wider than 1/20-th (5%) of the center wavelength of the spectrum.

The comparative plasmonic nanoparticles in FIGS. 2A-2D can be used for certain applications but their relatively broad linewidth of output emission limits the degree of multiplexing. Stimulated emission or lasing from plasmonic particles can greatly reduce the emission linewidth less than 1/50-th (2%) of the center wavelength. However, lasing from a single metal core-fluorescent shell structure has not been demonstrated in the comparative examples, or is at least unreliable. The insufficient optical gain from the fluorescent dye cannot compensate for the nanoparticle's loss or fluorescent quenching in the vicinity of the metal core.

### Plasmonic Laser Particles

The present disclosure sets forth a design recipe for three-dimensional plasmonic lasers in the form of particles, methods for making the particles, and apparatus for generating laser emission from the particles for applications. The laser particle uses semiconductor material to obtain high optical gain and high refractive index. Additionally, the particle has a metal coating in one or more parts of their surfaces or their entire surface. The metal layer has a typical thickness in the order of their plasmonic skin depth. When sufficient energy fluence is provided to the plasmonic laser particle, typical one or possibly multiple plasmonic cavity modes are excited and reach lasing threshold and thereby generate stimulated emission with a narrow modal linewidth, for example less than 5 nm for plasmonic polariton lasing or less than 40 nm for localized plasmon lasing. The various examples disclosed herein provide advantages over the comparative examples, at least in that they are in the form of particles comprising semiconductor and metals and capable of generating narrowband laser light or stimulated emission. Unlike comparative laser particles, the plasmonic laser particles set forth herein harness free electrons in metals so that spectrally narrowband stimulated emission can be produced with smaller sizes of particles.

The plasmonic laser particles described in this disclosure are based on two different mechanisms. One is the resonance of plasmonic polaritons, which are couplings between photons and the plasmons, and the other is owing to the resonance of plasmons within metals. With judicious designs, choice of materials, and appropriate dimensions, the plasmonic resonance can make it possible to make laser particles with smaller sizes than conventional optical resonance-based laser particles. The size of the particle can be less than the optical wavelength in the air or even less than the optical wavelength in the semiconductor along its longest dimension. For example, the size can be smaller than 1 μm for plasmon laser particles producing stimulated emission in a spectral range of 1100-1500 nm. A large Purcell effect generated by surface plasmon modes allows for a significant reduction in lasing threshold. Such plasmonic laser particles can be integrated in various structures, samples, or systems, including biological cells and photonic chips.

The disclosed plasmonic lasers present at least two distinct differences from the comparative examples. First, the new lasers have a shape in the form of a particle, unlike comparative plasmonic lasers that use macroscopic planar substrates and therefore are not particles. The typical size of a single particle is less than 3 μm (e.g., 1 μm, 500 nm, or 200 nm) along the longest axis. Second, unlike comparative luminescent plasmonic nanoparticles, the plasmonic laser particles set forth herein produce stimulated emission dominantly over spontaneous emission. This is made possible by choosing appropriate gain materials, particularly semiconductor with high refractive indices and high optical gains larger than about 1000 cm⁻¹.

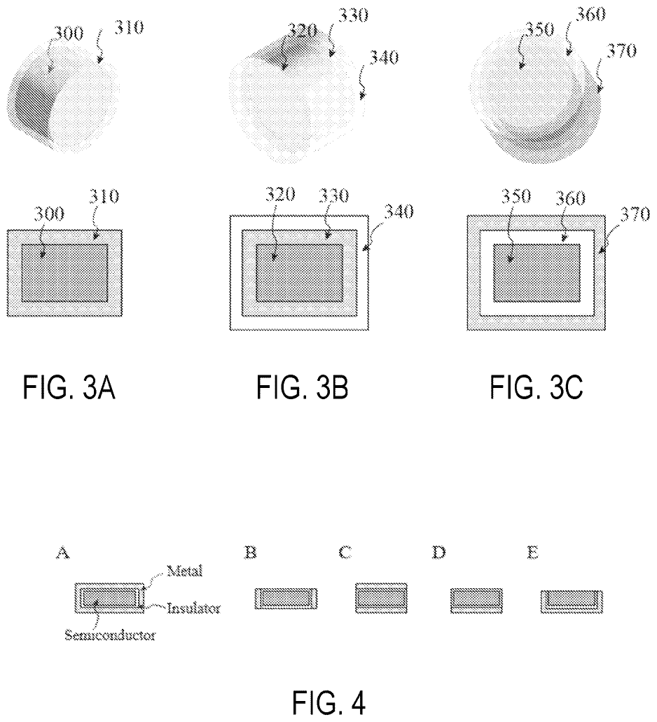

FIG. 3 illustrates schematic of three exemplary plasmonic laser particles using semiconductor, metal, and dielectric materials, with a discoidal shape. The simplest structure, shown in FIG. 3A, consists of a semiconductor gain medium 300 and an outer metal layer 310. Typically, the thickness of the metal layer is thinner or in the order of the skin depth of the metal so that light can propagate through the metal layer with substantial transmission efficiency. This particle may be encapsulated by an insulator layer 340, which can prevent chemical reactions of the semiconductor 320 and metal 330 with surrounding environment, such as aqueous medium and cytosol. In turn, the insulator 340 protects the materials 320 and 330 from degradation and increases the stability of stimulated emission. Alternatively, the semiconductor 350 may have a first insulating layer 360 and then a metal layer 370. The insulator layer can reduce quantum tunneling of electrons between the semiconductor and metal and enhance stimulated emission.

The metal layer may encapsulate the semiconductor completely in all surfaces, as shown in configuration A of FIG. 4. In the illustrated example, the metal layer will be present on all six surfaces for a cuboidal geometry. For discoidal geometry, the metal layer will be present on the top and bottom surfaces and the cylindrical surface. However, the metal layer may cover less than all external surfaces (e.g., only one or a few surface) of semiconductor. These examples are shown in configurations B-E of FIG. 4. In the example of a discoidal semiconductor, it may have metal coating on one/both of the flat surfaces (configurations C and D), around the cylindrical surface (configuration B), or combinations thereof (configuration E). Surface plasmonic modes are formed at or near the interface between the semiconductor and metal. For a microplate-shaped gain material, the metal coating can be placed on the whole surface (configuration A), the side surface (configuration B), both top and bottom surfaces (configuration C), bottom surface only (configuration D), and all surfaces except for the top surface (configuration E). For a spherical geometry, the metal layer may be present on all or only portions of the surface of the sphere.

Plasmonic materials include a noble metal (e.g., gold, silver, platinum), aluminum, and metallic alloys. Depending on the surface coverage, different three-dimensional plasmonic modes are formed, and an appropriate range for the metal coating thickness is determined. In the case of the side-only coating, surface plasmon modes traveling the microplate's circumference exist. Because the top and bottom surfaces are open, the pumping can be accessed through these open windows. Therefore, the thickness of the side coating can be thicker than the skin depth of the surface plasmon. In the case of the whole surface coating, the top and the bottom coating affects the penetration of pump light.

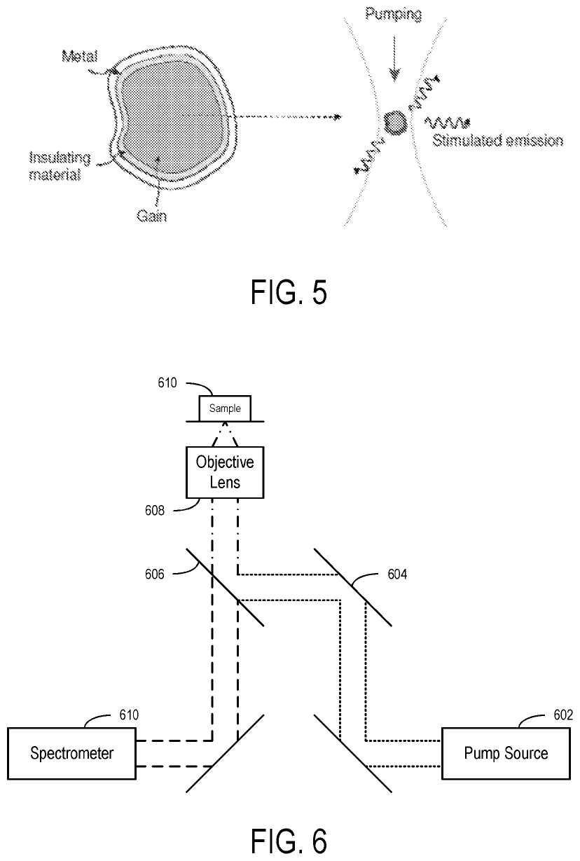

Plasmonic laser particles may be placed inside or on a desired environment or a sample. They are excited by appropriate pumping with sufficient energy fluence. This may be achieved by optical pumping, but electrical pumping is also possible. The excited particles that reach a lasing threshold generate narrowband stimulated emission, which can be readily measured over broader spontaneous emission with significantly lower spectral density. This is illustrated in FIG. 5. One or more laser particles may be placed in the voxel of the pumping beam. The particles may be floating or placed within liquids, embedded in solid materials or soft materials, placed on the surface of solid structures, or flying in the air, generating plasmonic stimulated emission.

The apparatus or system for using the stimulated emission from plasmonic laser particles includes pumping and detection. FIG. 6 shows a schematic of a microscopic readout setup, which employs a pump source and a spectrometer. Optical pumping refers to delivering optical energy to excite the gain material in the plasmonic particle laser. The pumping source 602 may be a pulsed laser with femto-, pico-, or nano-second duration, a continuous wave laser, incoherent sources such as light emitting diodes, or combinations thereof. The pulse duration is preferably close to or slightly shorter than the Purcell-accelerated carrier lifetime of the lasing plasmonic mode. For example, an InGaAsP disk laser coated with the metal may have a Purcell-accelerated carrier lifetime of a few tenths of a picosecond. The pumping source 602 illuminates the particle(s) of interest 610 via a scanner mirror 604, a dichroic mirror 606, and an objective lens 608. Upon absorbing the pumping energy, the particle(s) 610 can generate plasmonic stimulated emission. The emitted light may be collected by a lens and analyzed in a spectrometer 612. The output spectral characteristics are determined from the spectrometer data and recorded in a computer.

To compensate for plasmonic losses, the gain medium may be able to provide a large optical gain, for example greater than 1,000 cm⁻¹ and preferably exceeding 3,000 cm⁻¹. A long carrier diffusion length, for example greater than 1 μm, is preferred. Suitable gain materials include inorganic semiconductors, such as III-V compounds (e.g., InGaAsP, GaAs, GaN), II-VI compounds (e.g., CdS, CdSe, and ZnO), and lead halide perovskites (APbX₃, where A=CH₃NH₃ and Cs, where X═Cl, Br and I), as well as semiconductor quantum dot aggregates. The semiconductor gain medium may be comprised of single bulk compounds, heterostructures, quantum wells, and/or quasi two-dimensional geometry and can have various shapes including cubes, cuboids, microplates, wires, spheres, cylinders, rings, triangles, and/or hexagons.

The insulator or dielectric nano-spacer material can mitigate transports of photo-excited free electrons and holes between the semiconductor and metal and thereby minimize the loss of optical gain. Appropriate materials include silica (SiO₂), zirconium oxide (ZrO₂), magnesium fluoride (MgF₂), dielectric polymers such as poly-catecholamine or poly-vinyl-pyrrolidone, and lipid surfactants such as alkanethiol or cetrimonium bromide. The optimal thickness of the nanospacer depends on materials and may be around 5 nm, but can be thicker up to the plasmonic skin depth (1/e decay) of about 20 nm.

In certain gain materials, the Schottky barrier height between the semiconductor gain material and metal coating can be sufficiently high (e.g., >0.5 eV) that the charge quenching rate due to the metal can be lower than the radiative recombination rate. Then, a separate insulator may be omitted. The tunneling time of a Schottky barrier may be estimated to be approximately equal to q/(ART²exp (−Φ/k_{B}T)), where A is the heterojunction area, R is the Richardson constant, T is the temperature, q is the elementary charge, Φ is the Schottky barrier height, and kB is the Boltzmann constant. For example, the Schottky barrier height of an Au/InGaAsP heterojunction is reported to be in the range of 0.88 to 1 eV. At a temperature of 298K, the estimated electron tunneling time for an 800 nm sized disk with a height of 275 nm coated with gold is only about 10 msec, which is much slower than the radiative recombination lifetime of 1.5 ns. Therefore, the direct gold coating on InGaAsP particle without an insulating nanospacer layer can enable plasmonic lasing.

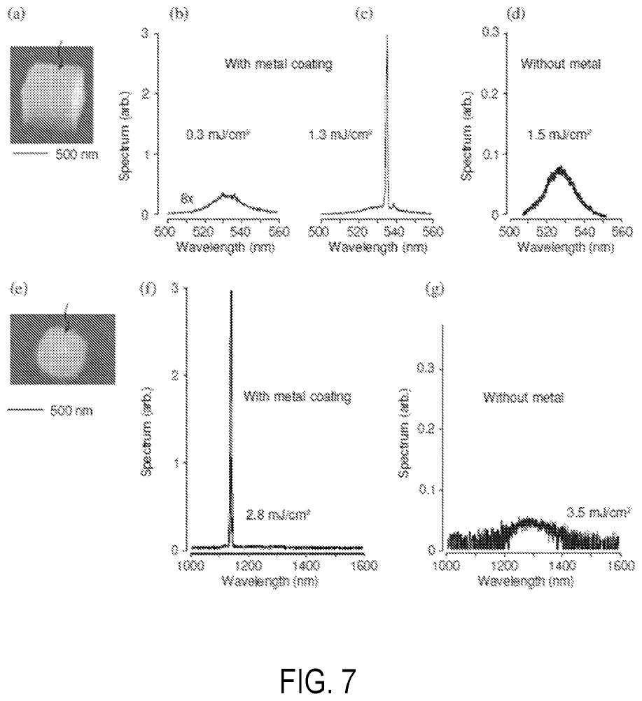

While the principles set forth herein may be embodied in a range of examples, two particular examples were experimentally realized. The representative data are shown in FIG. 7. The first prototype used perovskite semiconductors and gold coating to create a cuboidal-shape gold-coated perovskite particle (image (a) and graphs (c)-(d)). A 620-nm sized CsPbBr₃ particle was first coated with a 5 nm thick poly-norepinephrine (pNE) nanospacer and then a 15 nm thick layer of gold. Image (a) is a SEM image of the particle. Graphs (b) and (c) show the output spectra below the lasing threshold and above the lasing threshold, respectively. Graph (d) shows the output spectrum from a comparative CsPbBr₃ particle without a metal coating. No laser threshold was observed in the comparative particle even at high pump fluence levels close to the material damage threshold.

The second prototype uses InGaAsP semiconductor and gold coating (image (e) and graphs (f)-(g)). A 660-nm diameter InGaAsP disk was coated with a 10 nm layer of silica and then a 15 nm layer of gold. Image (e) is a SEM image of the particle. Graph (f) shows a lasing spectrum of the InGaAsP plasmonic particle above the lasing threshold, and graph (g) shows an output spectrum of a comparative InGaAsP disk of a similar size without metal coating.

As pumping sources, an optical parametric oscillator tuned at 480 nm (pulse width: 3 ns, repetition rate: 20 Hz) was used for the perovskite plasmonic laser particle and a picosecond laser at 760 nm (pulse width: 70 ns, repetition rate: 31 kHz) was used for the InGaAsP plasmonic laser particle. All measurements were taken at room temperature and in air. The threshold pump energies were measured to be 0.6 mJ/cm² and 1.8 mJ/cm², respectively. When the threshold energy was reached, the stimulated emission emerged, with spectral widths as narrow as 0.8 nm at 534 nm (graph (c)) and 4 nm at 1130 nm (graph (f)), respectively. The measured full-width-at-half-maxima (FWHM) linewidths correspond to 0.15% and 0.35% of the lasing wavelengths, respectively and at least 10 times narrower than the linewidth of spontaneous emission either below laser threshold (graph (b)) or from semiconductor-only materials of similar sizes without metals (graphs (d) and (g)).

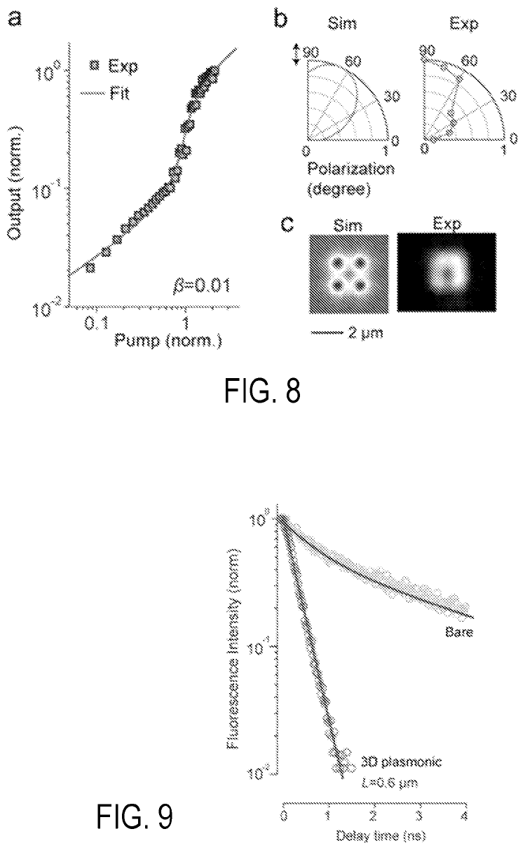

It can be seen that non-plasmonic metal-less semiconductor devices showed lasing when their sizes were greater than approximately 1 μm with sufficient pump fluences above threshold. In general, plasmonic laser particles can be smaller than comparative non-plasmonic laser particles. Additional evidence of lasing is provided by a nonlinear light-in-light-out curve, polarization in a specific direction, and a spatially coherent emission pattern (FIG. 8). In FIG. 8, graph (a) shows measured (squares) light-in-light-out curves and its fit (β=0.01). Graphs (b) and (c) show simulated (left) and measured (right) output polarization states of the Au-coated CsPbBr₃ particle. The second-order coherence, g₂, as a function of time delay may also serve as another defining metric of stimulated emission or laser emission. g₂ at zero delay can have a value of one for single mode laser emission and generally between 1 and 2 for multimode laser oscillations.

A large Purcell factor and large group index are beneficial for making small lasers. The lasing threshold in the radiative-loss dominant regime and low quantum yield material is inversely proportional to the product of the quality factor (Q), the Purcell factor (Fₚ), and the mode confinement factor (T). Plasmonic modes have relatively low Q factor values, typically in a range of 10 to 40, but relatively large Purcell factors due to their small mode volume. The latter effectively increase the quantum yield of the plasmonic modes. A large group index can increase the mode confinement factor and thereby help lowering the lasing threshold.

To measure the Purcell enhancement, time-resolved lifetime decay was measured, which confirmed accelerated fluorescence emission decay in plasmonic devices with metal coating compared to non-plasmonic devices without metal coating (FIG. 9). FIG. 9 shows time-resolved photoluminescence curves for a plasmonic laser particle with a side length of 600 nm (“3D plasmonic”), and for a non-metallic bare particle (“bare”). The solid lines are double-exponential fit curves to the experimental data. The reduced decay time of plasmonic modes may be more favorably excited by picosecond pumping (e.g., 10-500 ps) than nanosecond pumping (e.g., 1-10 ns). Pumping with even shorter pulses (e.g., 100 fs-10 ps) is also possible.

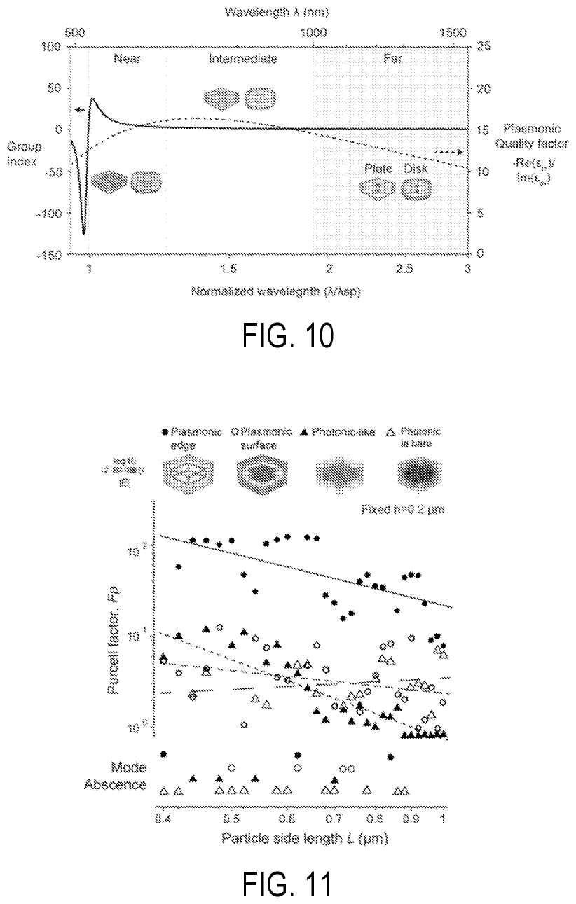

FIG. 10 illustrates the calculated spatial electric-field profiles of plasmonic modes in cuboidal and discoidal plasmonic particles for the typical optoelectronic properties of gold. In particular, FIG. 10 shows dispersion, Q-factor, and field profiles of plasmonic modes at different wavelengths for two representative devices with plate and disk shapes, respectively, encapsulated by optically semi-transparent gold layers. The group index decreases as the wavelength moves away from a dispersion asymptote. The metallic quality factor, which is the ratio of the real and imaginary parts of the metallic permittivity, varies between 10 and 20.

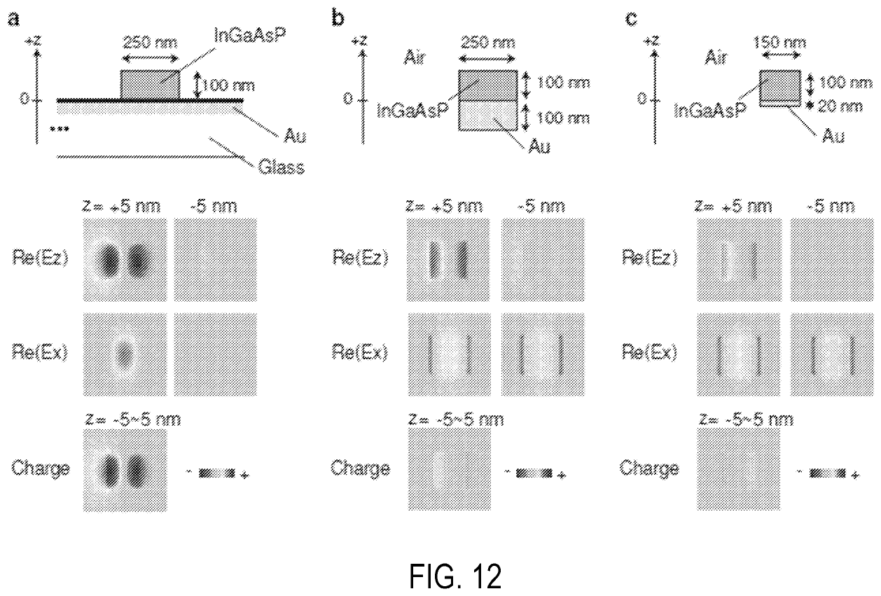

FIG. 11 shows the calculated Purcell factors Fₚ vs. particle side length L of various cavity resonance modes (plasmonic edge modes in solid circles, plasmonic surface modes in open circles, and photonic-like mode in plasmonic laser particles in solid triangles) in plasmonic laser particles, in comparison to photonic resonance modes (non-metallic bare particles in open triangles) in conventional non-metallic laser particles. The particle side length L was varied from 400 nm to 1.1 μm for a fixed device height of 200 nm. The gold metal thickness of plasmonic devices was 15 nm, and the surrounding environment of the devices was air. The plasmonic edge modes exhibit the highest Purcell factors.

When the particle has a volume smaller than subwavelength or <(λ/2n_{eff})³, the device does not support any plasmonic polariton modes since the device size is smaller than the wavelength of the mode. However, the metallic structure can still support localized surface plasmon resonance (LSPR) in the metal. When high gain provided by semiconductor compensates for the optical loss or of the localized surface plasmon oscillation, then lasing of the plasmonic oscillation can be achieved. This principle is essentially the same as that of lasers, but since it involves oscillation of free electrons, rather than photons or polaritons, such a device is also referred to surface plasmon amplification by stimulated emission of radiation or “spaser”. For example, the size of an InGaAsP-based particle can be smaller than 200 nm for a stimulated emission wavelength of 1400 nm. The plasmonic oscillation can generate electromagnetic radiation through scattering. The linewidth of the LSPR-induced output emission can be substantially reduced when the device is operated in the stimulated emission regime above lasing threshold, compared to the conventional spontaneous emission regime of the comparative example shown in FIGS. 2A-2D. Finite difference time domain (FDTD) simulations were performed to demonstrate LSPR in plasmonic laser particles with subwavelength sizes. FIG. 12 illustrates example schematics of three different spasers and calculated profiles of the electric fields and charges. The gain medium is an InGaAsP cuboid (side length=250 nm, height=100 nm) for each column, but the metallic parts are different. FIG. 12 column a shows a semiconductor-on-chip device with a bulk, planar gold substrate. When the substrate is replaced by metallic layer (e.g., a 100-nm thick gold attached to the semiconductor as in column b) or coating on semiconductor (e.g., a 20-nm thick gold layer as in column c), the particles can support LSPR modes. The lasing wavelength of LSPR-based laser particles is typically 10-20 nm red-shifted from the resonance with an infinite plate.

Further experiments were performed to test the feasibility of subwavelength plasmonic lasers (or spaser). FIG. 13 shows an experimental demonstration of a prototype device and its output spectra at various nanosecond pump intensities. The device is comprised of an InGaAsP particle with a width of about 200 nm and a height of about 80 nm and a planar gold substrate at room temperature. Image (a) is a SEM image of the InGaAsP on the gold substrate. Graph (b) shows output spectra from the spaser for different pump fluence levels. Lasing occurs for pump levles higher than 0.4 mJ/cm². When the pump fluence was below 0.05 mJ/cm², spontaneous emission was dominant. However, when the pump fluence levels was 0.4 mJ/cm², a resonant peak at 1270 nm clearly emerged. The peak was further amplified as the pump fluence was increased. The FWHM linewidth of the amplified LSPR mode ranged from 20 to 40 nm. This linewidth is limited by the intrinsically low Q factor of the LSPR mode. When InGaAsP particles of similar sizes were placed on a non-metallic substrate, LSPR peaks were not observed (graph (c)). These experimental results demonstrate the feasibility of LSPR-based plasmonic laser or spaser particles.

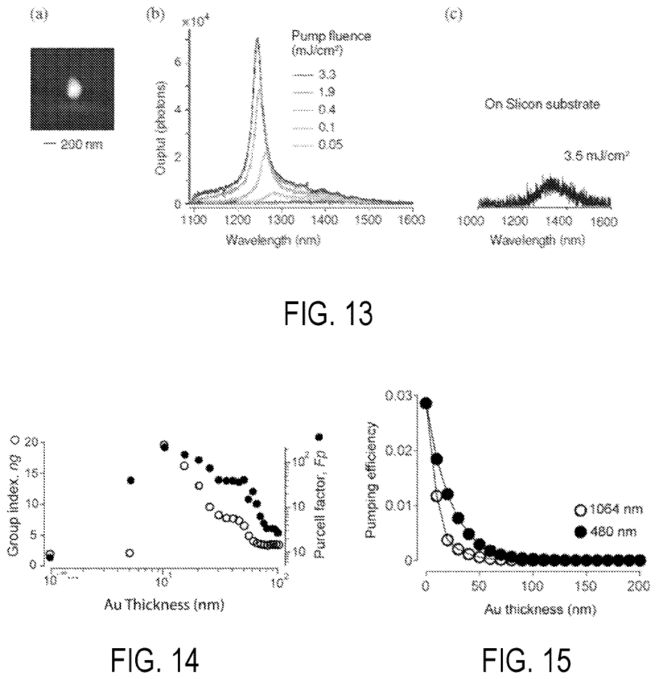

Plasmonic modes near the asymptote have low Q factors of ~20 due to high absorption loss of the metal. FIG. 14 shows the calculated group index ng and Purcell factor Fₚ for plasmonic waves in perovskite microplates (n=2.3, side length=600 nm, height=200 nm) coated with different gold thickness t in air (n=1) by using FDTD simulation. When the gold thickness was in between 10 and 60 nm, the Purcell factor increases significantly from the plateau of the unity in the particles coated with the thick gold of >60 nm. Fp reaches the maximum of ~200 at a thickness of ~10 nm and decreases steeply toward 1 as the thickness of gold film is reduced to zero. The Purcell factor and group index show similar trends as a function of gold thickness.

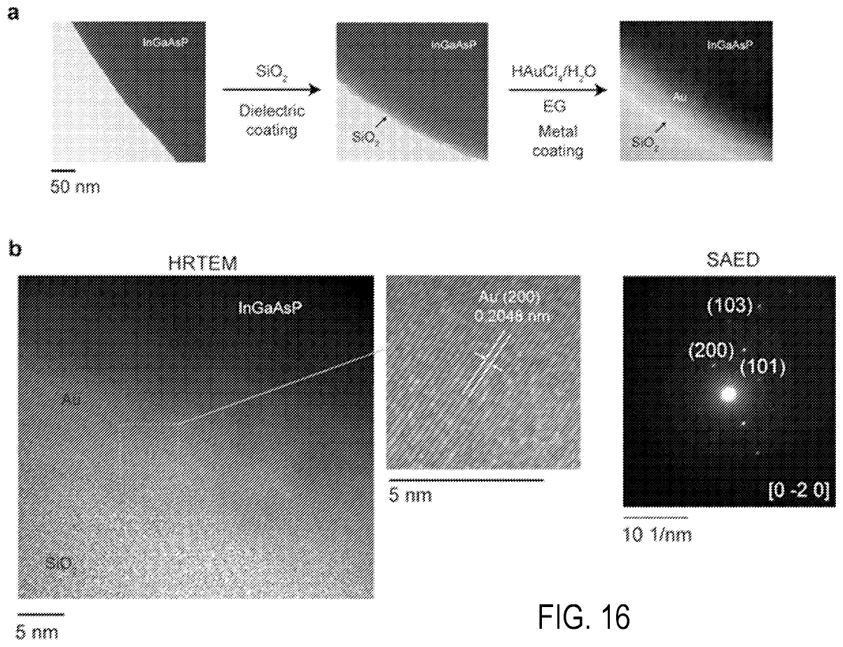

The metal thickness determines the reflectivity of metal and thus affects how well the optical pump light penetrates into the gain medium through the metal layer. In turn, the metal thickness influences the output intensity of plasmonic stimulated radiation from the particle. The reflectivity also varies with the optical wavelength. FIG. 15 shows theoretical results for the amount of pump light through gold layers of different thickness for two different wavelengths, 480 nm (solid circles) and 1064 nm (open circles), respectively. A gold coated InGaAsP particle with a diameter of 900 nm and a height of 200 nm was considered. For a gold thickness of 40 nm, only 5% of 1064 nm pump light illuminating the particle is ended up absorbed in the InGaAsP core. For 480 nm, 20% of illuminating energy can be absorbed by the InGaAsP semiconductor. In terms of lasing threshold and pumping efficiency, a metal thickness is between 10 nm to 30 nm is preferable. Nonetheless, thicker gold layers may be used when only a part of the particles are coated with the metal. Furthermore, different gold thickness can be employed.

Plasmonic laser particles may be fabricated by coating metal on semiconductor gain particle. Additional steps can be performed to prepare insulator layers. Micro- and nano-scaled gain material with specific geometry can be prepared by top-down lithography (i.e., III-V compound), solution-based crystallization (i.e., lead halide perovskite), hot chamber growth (i.e., II-VI compound), or droplet-assisted aggregation (i.e., quantum dots, fluorescent dye, or conjugate fluorescent polymer).

Insulating nanospacers with a thickness of a few nanometers can be formed by using solution-based chemistry (i.e., the sol-gel process for silica, polymerization for catechol amine, encapsulation of the lipid surfactant), atomic layer deposition (i.e., aluminum oxide), and the direct oxidation of gain material. The thickness and the uniformity of the nanospacer layer can be rationally controlled by changing reaction temperature, time, and precursor concentration.

Metal coating can be formed on the top of the nano-spacer layer (or on the surface of semiconductor). The metal coating process can be categorized into two types: bottom-up wet chemistry and metal sputtering or electron-beam evaporation. The bottom-up wet chemistry utilizes the reduction chemistry of metal ions. There are two different seeding methods: in-situ seeding and pre-synthesized seeding. In-situ seeding reaction is used to generate metal films on semiconductor surfaces. This process involves the spontaneous reduction of metal ions in solution to form metal nanoparticles or seeds on the surface of a semiconductor core. The metal film is then grown from these seeds by consuming the semiconductor core.

To generate uniform gold coating on InGaAsP particles, a specific in-situ seeding method was developed using a SiO₂ matrix, which controls the diffusion of gold ions and the coating reaction on InGaAsP. To prevent vigorous reduction reaction between gold ions and the semiconductor core, the particles were first coated with a 10-15 nm thickness of SiO₂ by sol-gel reaction. This coating slows down the reduction reaction by limiting the diffusion of gold ions through the matrix, resulting in a more uniform metal coating on the circumference of the InGaAsP particles. This is shown in FIG. 16, in which image (a) presents representative TEMs of InGaAsP-based laser particles before and after silica coating and gold film depositions; and image (b) presents representative high-resolution TEMs of the gold film layer showing different lattice fringes of the gold. The inset of image (b) presents the 200-plane of the gold with 0.2048 nm fringe. A selected area electron diffraction (SAED) pattern of the designated area is also shown. The silica coated InGaAsP particles were dispersed in a solution of 4 M hydrogen tetrachloroaurate (HAuCl₄) in water and 2 mL of ethylene glycol (EG) and incubated at 90° C. for 3 hours. This process yielded a 15-20 nm thickness gold coating between the SiO₂ and InGaAsP. The resulting gold coating is single crystalline and matches with the InGaAsP (202) plane with only 2.25% mismatch. This is confirmed by high resolution transmission electron micrograph (HRTEM) and selected area electron diffraction (SAED) pattern analysis. The silica layer surrounding the gold layer also serves as a protective, surface-passivation layer.

Many in-situ seeding reactions may be used for producing metal films on semiconductor surfaces with high uniformity and crystal quality. The chemistry described here is just one example of the many variations of this process that can be used depending on the specific materials and applications involved.

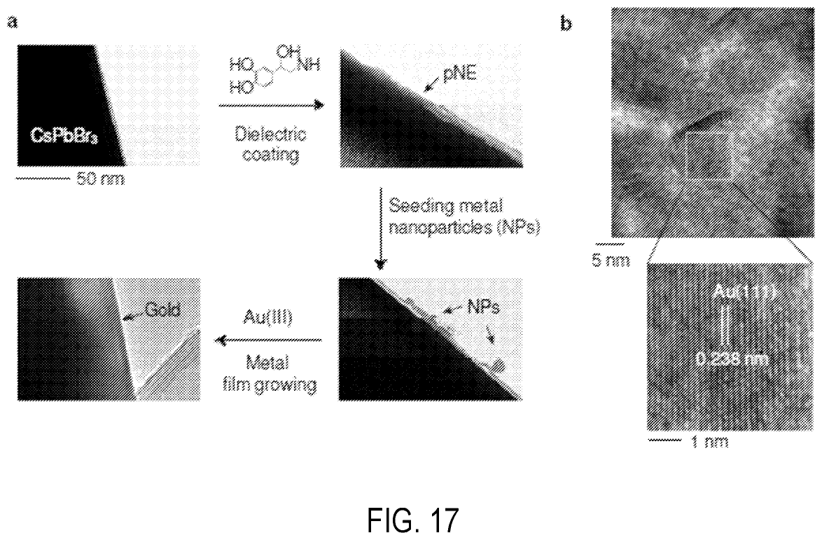

The second approach, pre-synthesized seeding method, harnesses metallic nanoparticles as seeds. A reduction chemistry allows the nanoparticle seeds to grow in size. The initial size of the nanoparticles determines the thickness of the finally formed metal film layer. This method is well suited for semiconductors, such as perovskites, which are dissolved in water. This technique was used to produce the gold coated CsPbBr₃ particle shown in FIG. 7, image (a). First, cuboidal CsPbBr₃ crystals were coated with poly-norepinephrine (pNE) with a nano-scale thickness. Then, 10 nm-sized gold nanoparticles were seeded on the pNE nanospacer surface by incubating the particles in ethanol overnight. Then, HAuBr₄, NaOH and formaldehyde were added or light irradiation such as room light was used to grow polycrystalline gold with a 15 nm thickness. The TEM images of the surfaces at different stages are shown in FIG. 17, image (a). FIG. 17, image (b) is a representative HRTEM image of the gold-coating layer. The highlighted region (inset) presents the gold 111-plane with 0.238 nm fringe.

It is possible to coat only one flat surface of semiconductor particles using hydrophilic and hydrophobic interfaces. For this, insulator-coated semiconductor particles are functionalized with hydrophobic moieties, such as long alkane-chained surfactant, and dispersed in the hydrophobic solvent, such as dodecane and chloroform. Water or hydrophilic solution, such as N,N-dimethyl formaldehyde, is prepared for metal reduction chemistry. This solution should not have miscibility to the designated hydrophobic solvent. The hydrophobic solvent with semiconductor particles and the hydrophilic solvent with precursors are placed in the same vial or reaction tube. Spontaneous crystallization of the metal in the hydrophilic solvent by supersaturation can result in metal coating on the side of the particles toward the hydrophilic interface. Infiltrated electron-beam evaporation is another method for metal coating. Silica coated III-V semiconductor particles are placed on a mesoporous polymer (e.g., polystyrene) coated substrate. Then metals are deposited through electron-beam evaporation. After metal deposition, the mesoporous polymer layers can be removed in the solution, which releases the metal-coated particles.

Because the metal coating can improve the confinement of the optical energy, the plasmonic stimulated emission wavelength can be less sensitive to the refractive index change of the surrounding medium compared to conventional non-metallic laser particles. The metal coating of plasmonic laser particles can protect the semiconductor gain materials from reactive chemicals in the surrounding medium. This can reduce the degradation of semiconductor materials and output laser emission characteristics. The metal coating of plasmonic laser particles can also help to attach functional materials, such as proteins, lipids, polymers, magnetic nanoparticles, genetic materials, quantum dots, plasmonic nanoparticles, and single organic molecules, on the surface of the laser particles. Additionally, plasmonic laser particles may be used for generating photothermal effects, such as photothermal ablation, using excessively high-power pump light. Several examples in which the plasmonic laser particles described herein may be used are described in detail.

### Half-Wave Nanolasers and Intracellular Plasmonic Lasing Particles

Resonant systems have a fundamental oscillation frequency at which the entire resonator precisely contains half wave of oscillation (or quarter wave for asymmetric resonators). Many electrical, acoustical, and mechanical oscillators typically operate at these fundamental frequencies. In an optical laser, the fundamental oscillation corresponds to a mode with a wavelength (2) equal to half (or a quarter) of the resonator's length divided by its refractive index (n). However, comparative example lasers have operated at harmonics, utilizing oversized resonators. For a given wavelength, the smallest laser size could be achieved by employing the lowest-order mode.

The plasmonic laser particles described herein provide an approach for developing small lasers with volumes approaching the diffraction limit. Surface plasmon polaritons (SPP) facilitate achieving subwavelength mode volumes (Vm), which, through the Purcell effect, allows for higher gain extraction from gain media. Lasing is achieved when the gain overcomes the large radiation and absorption losses of small metallic cavities. Thus, the present disclosure provides for the fundamental-mode oscillation from half-wavelength nanolasers at room temperature. In one example, the laser comprises a III-V semiconductor particle, as small as 190 nm for λ=1190 nm, on a gold substrate. This section describes the design principles and operation in the near infrared (NIR) away from the surface plasmonic frequency. Additionally, moving away from the substrate-based design, this section develops substrate-free plasmonic laser particles (LPs). Using submicron particles emitting single mode peaks tunable across a wide spectral range, plasmonic lasing within live cells is demonstrated for biomedical applications.

In comparative attempts at nanoscale spasers based on localized surface plasmons (LSP), several challenges were presented as can be understood from a simple gain-loss analysis. To reach the lasing threshold, the theoretical minimum pumping rate required is Mω/Q, where M denotes the number of modes the pump energy is distributed to, ω is the optical frequency, and Q is the cavity quality factor. At least ωτₛ/Q gain emitters are needed to absorb the pump energy, where τₛ is the spontaneous radiative lifetime, which is modified from its free-space value to by a Purcell factor

$${F}_{p} = \frac{3 {τ}_{0} Q}{4 {π}^{2} {V}_{m}} {( \frac{λ}{n} )}^{3} .$$

When gain bandwidth Δω is broader than cavity bandwidth ω/Q, the minimal emitter density ρₘᵢₙ must exceed

$$∼ \frac{Δ {ωτ}_{0}}{Q} {( \frac{λ}{2 n} )}^{- 3} .$$

For instance, in a single-mode (M=1) resonator with Δω=3×10¹⁴ s⁻¹, τ₀=10⁻⁹ s, λ/2n=180 nm, and Q=10, ρₘᵢₙ is approximately 5×10¹⁸ cm⁻³. Achieving this density with fluorophores or quantum dots without significant nonradiative quenching is challenging. Moreover, deep-subwavelength metallic nanospheres would require greater pump energy due to their large M (>40), which would cause excessive heating.

The present disclosure addresses these challenges as follows. First, it is found that the non-radiative coupling to higher order plasmonic modes can be completely avoided in the NIR, significantly away from the surface plasmon frequency (ω_{SP}), achieving M=1. Second, the required high gain density can be achieved with bulk III-V semiconductors when driven substantially above their band gap. The outcome is a single lasing mode characterized as a half-wave plasmonic dipole.

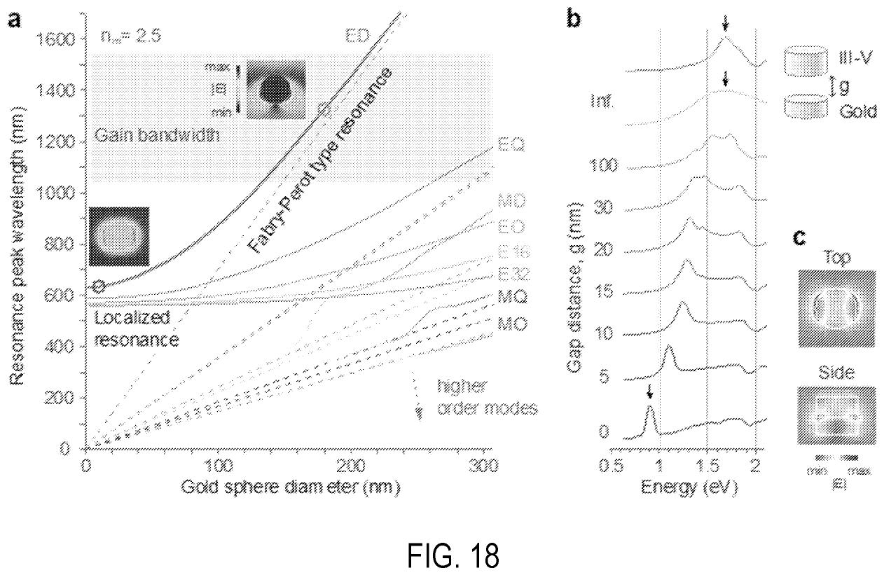

The general design concept can be explained across various particle structures, with reference to FIG. 18. Consider a gold sphere immersed in a medium with a refractive index (nₘ) of 2.5 (representing the effects of III-V gain medium and air). FIG. 18 graph (a) shows the theory for resonance peak wavelengths of a dozen of lowest plasmonic modes as analytic solutions of Mie scattering calculation. Solid curves are for gold, and dashed curves are for a perfect conductor with an infinite plasma frequency. For nanospheres with deep subwavelength diameters, the electric dipole (ED) and higher order modes (EQ to E32) converge within a narrow spectral range near 600 nm, corresponding to LSP resonances near ω_{SP}. In the insets, the electric (|E|) profiles of the ED modes in the quasi-static and dynamic regimes, respectively, are shown. As the diameter (d) exceeds the quasi-static limit, the resonance curves shift due to phase retardation effects. Beyond this transition, the magnetic modes (MD to MO) develop, and both electric and magnetic modes follow linear dispersion curves that intersect the origin. Besides this LSP picture, the dispersion relationship can be explained from the perspective of SPP waves. Farther away from ω_{SP}, the SPP wave refractive index becomes close to nₘ.

The asymptotic line for the ED corresponds to the half-wavelength Fabry-Perot (FP) resonance given by λ≈2.81nₘd, EQ has a slope of λ≈1.41nₘd, and so on. In the FP regime, only the ED mode can be placed within the gain bandwidth while all higher order modes are excluded. Near ω_{SP}, the SPP wavelength is significantly reduced, causing the dispersion curves to bend. In this view, LSP is the half-wave resonance of SPP near ω_{SP}, and comparative nano-lasers that utilize higher-order SPP waves can be viewed as the lasing of multipole LSP modes in the FP regime. Graph (b) shows simulated Mie scattering spectra of a complex of semiconductor (n=3.5) and gold nanodisks with the same diameter of 250 nm for different gap distances. Arrows indicate the locations of the ED modes. Graph (c) shows the electric field amplitude profiles of the semiconductor-gold structure in contact (dashed outline).

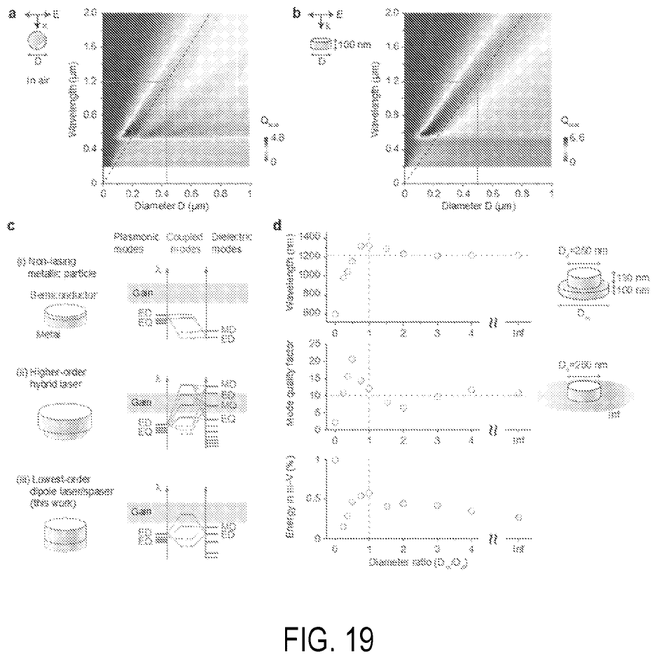

One insight gained from the dispersion curves is that while the ED in the quasi-static regime is spectrally close to other modes, leading to a large M, modal separation increases in the FP regime, allowing only the ED mode to fall within the wide bandwidth of a gain medium. This is illustrated in FIG. 19, which shows mode properties of metal-semiconductor nanoparticles. In FIG. 19, graphs (a) and (b) are Mie scattering spectra of gold nano-spheres (a) and gold nano-disks (b) in the air for planar incident waves. While the excitation of higher order modes is evident for spheres, only the fundamental electrical dipole mode clearly appears for disks owing to the symmetry; the higher modes in disks are not efficiently excited by the uniform driving field. In nanolasers, however, the higher-order plasmonic modes are driven by local emitters and can be efficiently excited via near-field interactions.

Graph (c) is a schematic depicting mode coupling between plasmonic and semiconductor disk modes for three representative cases: (i) non-lasing metallic luminescence when a semiconductor disk is too thin, in which case, because of the large differences of the modes in energy, mode coupling is weak, and the lowest order modes are largely plasmonic and because of the proximity of the modes, it is difficult to selectively amplify only the ED mode; (ii) higher-order hybrid laser, where multiple dielectric-like modes are present within a gain bandwidth; (iii) a hybrid dipole laser (spaser) where the individual modes in the metal and semiconductor disks have similar energies. Strong coupling occurs between ED modes, separating the hybrid plasmon-like mode from the other hybrid modes. This mode shift may be considered as the effect of the refractive index of the semiconductor on the plasmonic mode. However, mode coupling is a more accurate explanation as the effective index the plasmonic ED mode experiences is the same as the index of the ED mode in the dielectric medium. Note that the MD modes, the lowest order modes in dielectric disks, are not efficiently coupled with the plasmonic ED mode because of the field symmetry.

Graph (d) shows a FDTD simulation of metal-semiconductor disks with different diameters depicted in the inset. The resonance wavelength, quality factor, and mode confinement factor in the semiconductor vary as a function of the diameter ratio from 0 (III-V only) to infinity (on a gold substrate). The resonance wavelength of the hybrid ED mode increases dramatically from 600 nm to 1300 nm at size matching and then 1220 nm for oversized gold. The quality factor has the maximum at a diameter ratio of 0.5, in part due to the best mode energy matching and in part due to the lower metallic absorption at 800-900 nm. The Q factor approaches to slightly over 10 at infinite gold, where a quarter of electromagnetic energy residing in the semiconductor while the rest three quarters are stored in the metal.

The same design concept illustrated in FIG. 18, graph (a) is applied to gold nanodisks, to which III-V semiconductor nanodisks are attached to form metal-semiconductor lasers. FIG. 18, graph (b) depicts the Mie scattering spectra of a gold disk with a diameter (D) of 250 nm and a thickness of 100 nm, and a semiconductor disk with a refractive index of 3.5, matching diameter, and thickness of 130 nm. When the two disks are well separated, each exhibits its fundamental half-wave dipolar mode at 1.69 eV (λ=730 nm). As the two disks are brought closer, the modes are increasingly coupled, and the lowest-order hybrid ED mode emerges at 0.9 eV (1380 nm) upon contact. This fundamental mode spatially localizes at the metal-semiconductor interface (FIG. 18, graph (b)), and its resonance energy overlaps with the semiconductor gain (FIG. 19, graph (c)). A finite-difference time-domain (FDTD) analysis demonstrates that the strong mode coupling results in a cavity Q of up to 20. Notably, Q of ~10 is obtained when the gold disk is replaced by oversized plates (FIG. 19, graph (d)). This indicates that the edge of the semiconductor disk effectively provides both reflection (SPP picture) and charge localization (LSP picture). Also, it is noteworthy that the scale of the Q factor remains the same in the transition regime of SPP and LSP, regardless of the shape of the particle.

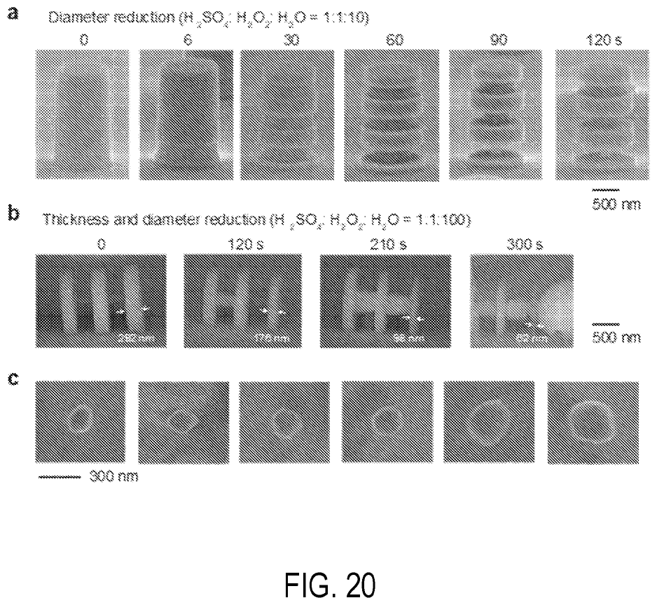

In experiments, InGaAsP particles were fabricated using a combination of dry and wet etching. The results are illustrated in FIG. 20. Image (a) shows two-dimensional etching for reducing the diameters of InGaAsP layers while preserving their thickness using piranha acid solution. The InP layer remains the same size while InGaAsP is etched away. The bottom layer with a composition of In_{0.53}Ga_{0.47}As_{0.92}P_{0.08} was primarily used in most experiments (unless specified). Image (b) shows the three-dimensional etching of InGaAsP layers, performed after a full (typically) or partial (for this dataset) etching of InP layers between InGaAsP layers. This process reduces both the thickness and lateral sizes. The 2D and 3D etching techniques were used to obtain desired thicknesses and sizes for InGaAsP particles. Image (c) shows SEM images of six particles obtained from a single batch targeting a thickness of 130 nm and a mean side length of 250 nm.

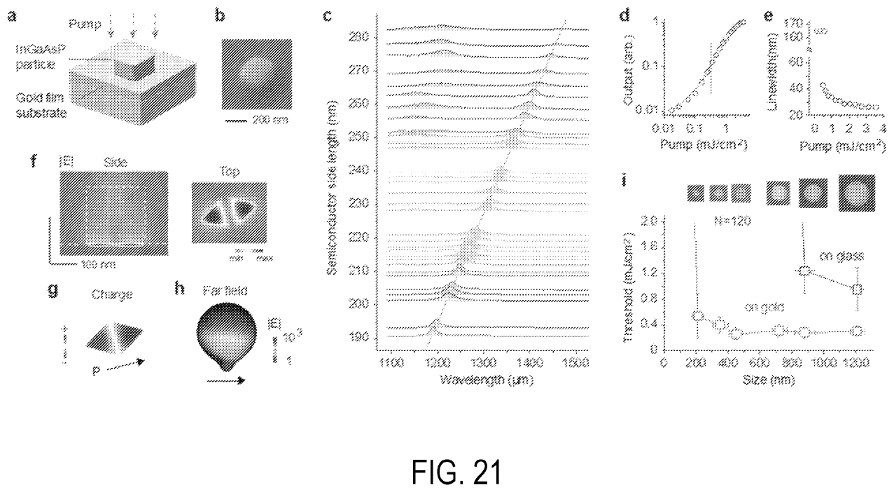

This batch was used to produce the experimental data in FIG. 21. In FIG. 21, image (a) shows a schematic of the semiconductor-on-gold design. Image (b) is a SEM image of an InGaAsP particle with a side length of 170 nm (280 nm corner-to-corner). Graph (c) shows emission spectra from particles with different sizes, in which the dotted line indicates FDTD-calculated tuning curve. Graph (d) includes a measured light-light curve (circles) of a sample and theoretical fit (solid curve, β=0.06). Graph (e) shows measured linewidth at different pump fluences. Image (f) illustrates the field amplitude |E|. Image (g) shows induced charge (∇·E). Image (h) shows a computed far-field pattern of a half-wave device. Graph (i) shows measured laser thresholds of several sample batches fabricated for different semiconductor sizes. The inset includes SEM images of representative samples from different batches.

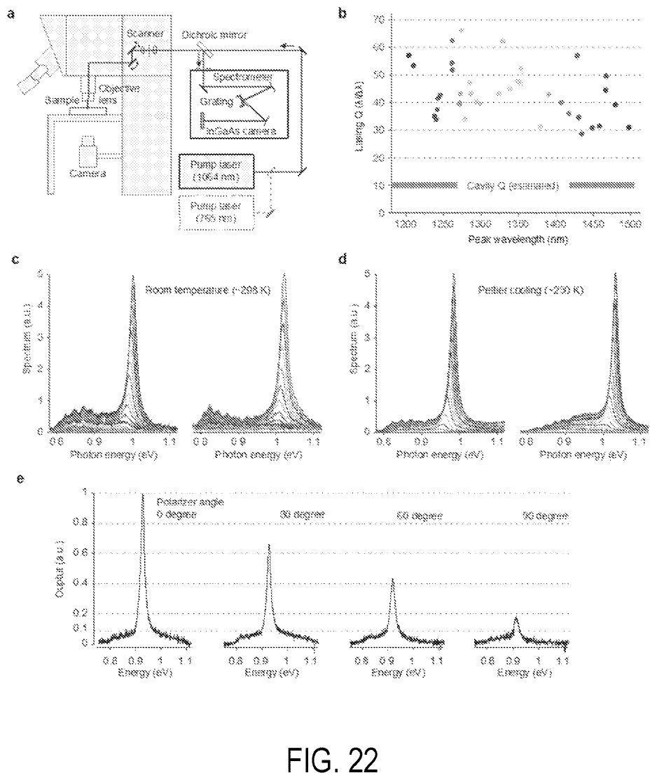

By controlling the etching time per batch, various particle sizes were produced ranging from 100 to 300 nm and a thickness of 130 nm. These particles typically exhibited rhombus shapes. The particles were placed on a high-quality polycrystalline gold substrate (FIG. 21, image (a)). A 1064-nm pump laser (2.5 MHz repetition and 2 ns pulse width) was employed, along with a grating-based InGaAs-camera spectrometer (0.8 nm resolution) (see FIG. 22, a). FIG. 21 graph (c) displays the emission spectra collected from 32 particles made of In_{0.53}Ga_{0.47}As_{0.92}P_{0.08} at pump fluences of ~2 mJ/cm². The spectra are arranged along a theoretical tuning slope described by λ≈3.09 x+596 (nm), where x represents the side-length of the rhombus. Particles smaller than 250 nm exhibit single emission peaks at wavelengths as short as 1200 nm (~370 nm lower than the band gap edge near 1570 nm). For larger particles, second peaks are observed, attributed to the ED modes along the shorter axes of the particles. Experiments were also conducted with InGaAsP particles coated with a 5-nm thick insulating layer of silica and provided similar results, likely due to the surface roughness of the InGaAsP particles.

As the pump fluence was varied, each particle showed nonlinear intensity growth, spectral narrowing, and single polarization peak over quasi-unpolarized background. This is shown in FIG. 22. Inset (a) shows a schematic of a microscope setup used for optical characterizations. Graph (b) shows measured lasing linewidth Q factors of 40 devices with different sizes and shapes. Representative spectra are displayed in graph (c) of FIG. 21. In graph (c) of FIG. 22, emission spectra of two devices at a room temperature of 298 K are shown. Graph (d) presents two devices at a Peltier cooled temperature of ~230 K (nominal). Compared to the room temperature spectra, the falling edges at the high energy side, or near the quasi-Fermi levels, are steeper, presumably due to slightly reduced thermal excitations at the lower temperature. Note that the computer simulation spectra exhibit ever steeper spectral falloff at the quasi-Fermi level, because no thermal excitations have been considered in the model, which corresponds to zero-degree temperature (0 K). Graph (e) shows output spectra through a polarizer at different angles. The stimulated emission peak at 0.94 eV (1321 nm) is linear polarized while the broad lower-energy background above the peak (0.75 to 0.9 eV) is approximately unpolarized.

Varying the pump fluence provided one device having size about 245 nm displayed a threshold at 350 μJ/cm² with a fitted β factor of 0.06 (FIG. 21 graph (d)), and an output spectrum at 1350 nm with a linewidth of 27 nm (a linewidth Q of 50), which is about six times narrower than spontaneous emission linewidth of 165 nm (FIG. 21 graph (e) and FIG. 22 graph (b)). The observed high β factor due to small number of the modes in the nanocavity and Purcell acceleration, and carrier saturation generate relatively blunt nonlinearity in the input-output curve. The sharp drop in linewidth near the threshold is attributed to the appearance of the lasing peak on broad spontaneous background. In FDTD simulation, only one resonance mode was found within the broad fluorescence bandwidth. The electric field and plasmon charges localize at the gold-SiO₂ interface, generating far-field emission that can be efficiently collected in the vertical direction by an objective lens (FIG. 21, images (f)-(h)).

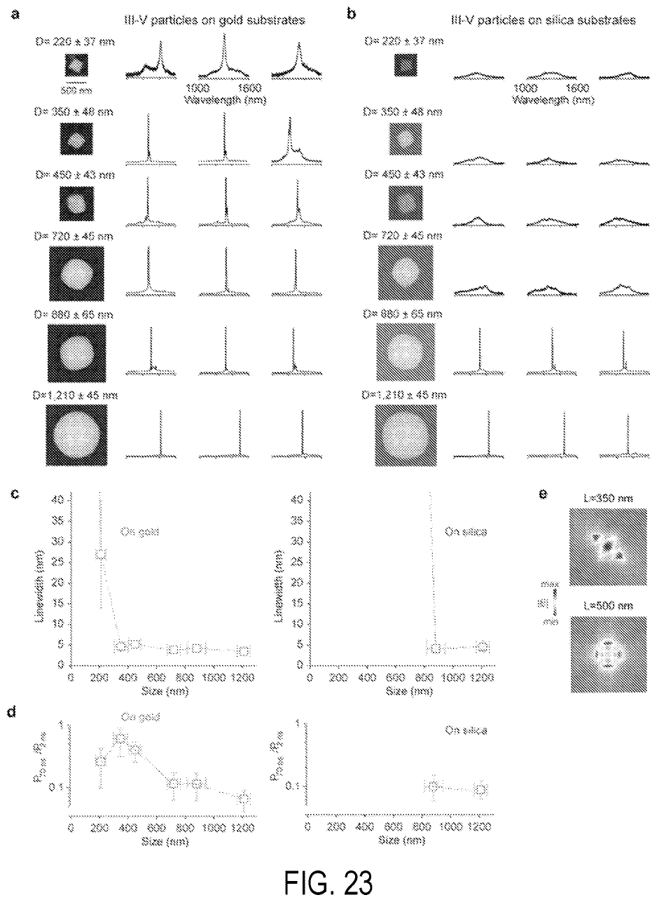

Particles on a gold substrate (plasmonic devices) were compared with those on silica-coated silicon substrates (dielectric devices). A total of 120 devices produced from 6 batches were examined, each with different average particle sizes and thickness of approximately 290 nm. This is shown in FIG. 23. Columns (a) and (b) shows characteristics of representative devices from different batches of varying sizes (same thickness of 290 nm) for plasmonic (a) and dielectric cavities (b). Dielectric devices with less than 880 nm sizes did not reach lasing threshold even at the highest pump power levels. Graphs (c) and (d) show mission linewidths (c) and the ratio between the peak threshold power for picoseconds and nanoseconds pumping (d) measured from a total of 120 devices. The threshold pump fluences of these devices are shown in FIG. 21. Graph (e) of FIG. 23 provides FDTD results of a 350-nm rhombus-shape showing a second order mode at 1206 nm (top) and a rectangular-shape 500-nm device showing a whispering gallery mode (Q=94) at 1164 nm (bottom).

As the particle size increased, along with the oscillating mode order, the threshold showed a modest decrease (see image (g) of FIG. 21), and the linewidth significantly reduced to 4-6 nm (resulting in a linewidth Q of 240-340). For dielectric devices, lasing was observed only for particle sizes larger than 880 nm, even at the highest pump fluence up to 8 mJ/cm². The peak threshold power difference between nanoseconds and picoseconds pumping of the same device in different size batches were also compared. Picoseconds pumping is approximately 0.1 to 0.6 lower than nanoseconds pumping, primarily due to the accelerated lifetime of the carriers by the Purcell effect (graph (d) of FIG. 23).

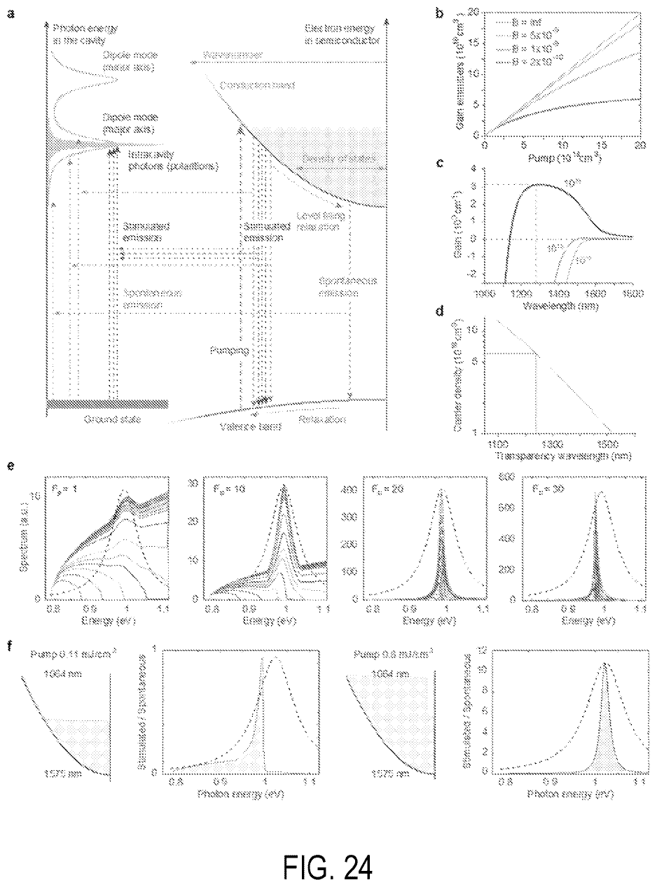

FIG. 24 shows semiconductor gain and a “waterfall” laser model. Graph (a) is an energy level diagram with various transitions paths in a semiconductor laser. This forms essentially a four-level laser system (or a quasi-three-level including valence band absorption of intracavity light). The blue shade represents free electrons (or the electron-hole plasma) that fill the electronic states in the conduction band. Graph (b) is an analysis of charge carrier loss due to Auger recombination for bulk (blue) and Purcell-enhanced (yellow) radiative decays. Graph (c) shows gain profiles at room temperature at three different carrier density levels, calculated using standard semiconductor theory considering the Fermi-Dirac distribution of the carriers at room temperature. The thermodynamic excitation was neglected in thew numerical modeling in this section, which makes a sharp gain cliff beyond the quasi-Fermi level. Graph (d) shows calculated total carrier density versus transparency (zero-gain) wavelength. Graph (e) shows simulated output spectra of a device with a size of 240 nm for the cases of different Purcell factors, from 1 to 30, as the pump fluence is varied from 0.021 to 2.1 mJ/cm². The output saturates. The dashed curve illustrates the cold-cavity mode profile with a Q factor of 10. At Fₚ=1, the lasing threshold is never reached even at extreme pumping. At Fₚ=10, the lasing threshold is barely reached with a stimulated-to-spontaneous ratio of 1.07. Compared to Fₚ=20, Fₚ=30 results in reduced linewidths. The best correspondence to experimental data was obtained with Fₚ=18 (Device 1) and Fₚ=19. In graph (f), the emitter population and stimulated-to-spontaneous ratio at a threshold pump fluence are shown at left, at which the quasi-Fermi level is just below the modal resonant frequency. At a pump level 7.3 times above the threshold when all the entire excited states are almost filled, shown at right.

Building on the standard semiconductor laser model of FIG. 24, Rate equations in the spectral domain were shown. The model did not explicitly consider expected spatial dependence in spontaneous and stimulated emission rates and the accompanying depletion and diffusion of electron-hole pairs, treating them as spatially averaged parameters. Given the band gap edge at 1570 nm and under optical pumping at 1064 nm, the total number of gain emitters available is estimated to be ~1×10¹⁹ cm³. This large concentration of carriers is normally not reachable due to the Auger recombination (~2.3×10⁻²⁹ cm⁶/s for InGaAsP) but is attained in plasmonic cavities due to the enhanced radiative emission. Within the mode bandwidth ΔΩ (=ω/Q) centered at 1240 nm, the number of gain emitters is 3.4×10¹⁸ cm⁻³ for Q=10. In a bulk semiconductor, the theoretical maximum free-space gain would be around 3,000 cm⁻¹ at 1240 nm, which is insufficient to compensate for the cavity loss (2nπ/λQ) of ~17,700 cm⁻¹. Within a subwavelength cavity, the cavity gain is enhanced by the Purcell factor Fₚ (graph (e) of FIG. 24), making it possible to reach the threshold.

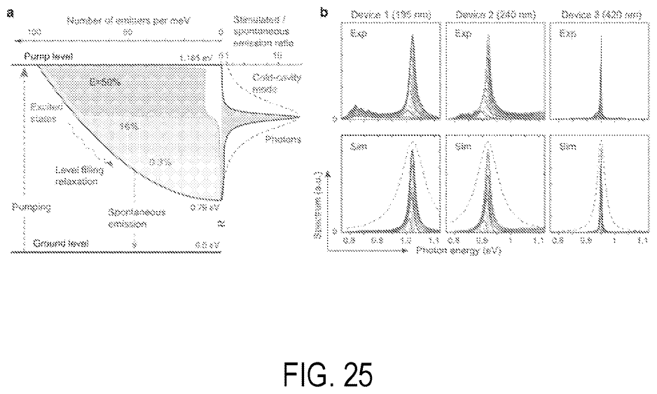

FIG. 25 is a simplified “waterfall” model based on diagram (a) of FIG. 24. Diagram (a) of FIG. 25 is an energy diagram of gain emitters (electron-hole pairs) and photons (polaritons) in a cavity. The population in the excited states (blue shades) and output spectra (cyan) are illustrated for a 240 nm-size device at a pump fluence of 0.8 mJ/cm². In the beginning of a pump pulse (0.3% of the total pump energy), only the bottom excited states are filled. As the pump increases (to 16%), the quasi-Fermi level elevates to the mode center frequency, at which the threshold has been reached. At the peak of the pump pulse (50% energy), stimulated emission becomes greater than the spontaneous emission of the mode. Graph (b) shows a comparison of simulation and experiment for two lowest-order (half-wave) devices (simulated Q=10) and one high-order device (simulated Q=30), for a range of pump fluence from 0.03 to 3 mJ/cm². A periodic spectral fringe appears between 0.8 and 0.88 eV owing to internal interference in a dichroic mirror in the setup.

The numerical simulation closely reproduced the experimental results. FIG. 25, graph (b) illustrates the measured and simulated spectra of two lowest-order (half-wavelength) devices and a one-wavelength device. At low pump power levels, only spontaneous emission near the band edge is evident. As the pump increases, the excited band fills up, and the spontaneous emission peak shifts toward higher energies. With stronger pumping, photons (polaritons) accumulate in the cavity, and eventually stimulated emission becomes greater than spontaneous emission. Upon reaching this threshold, a narrowing of the linewidth occurs, and the increase in the number of photons shows nonlinear growth. A kink, which is characteristic of a small spontaneous emission factor β«1, appears even when only one mode present in the gain bandwidth. This apparent kink in the light-in-light-out curve results from level filling; the amplification of the mode has to wait for the quasi-Fermi level of the emitters reaches the mode resonance. The so-called threshold-less lasing is not possible in this case. The roll-off of the output power at higher pump levels can be attributed to increasing nonradiative Auger recombination. Ultimately, the output saturates when all excited states have been populated. When comparing the results at room temperature to those from Peltier-cooled samples, a modest spectral narrowing was observed (FIG. 22 graph (d)).

The high performance of the gold-InGaAsP constructs supports the development of substrate-free plasmonic lasers that are injectable or implantable in biological systems. Miniaturized LPs are further usable for super-resolution imaging and intracellular sensing, causing minimal perturbation, especially valuable in the NIR range, outside the comparative 400-800 nm window available for fluorescence measurements.

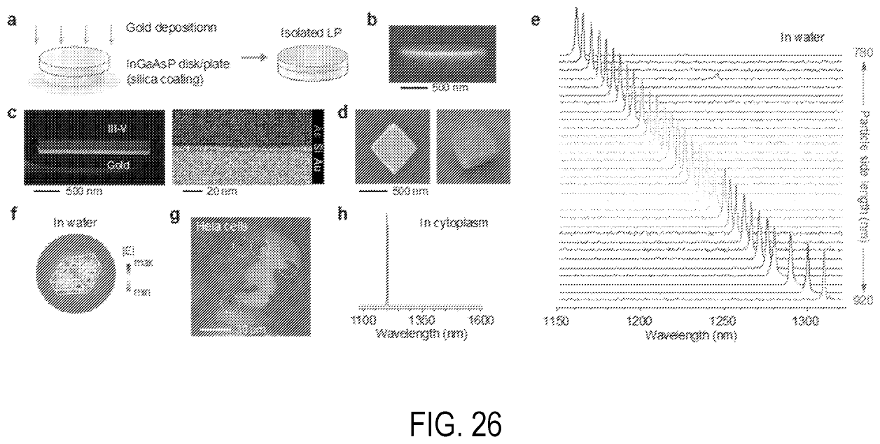

To create metal-semiconductor particles, In_{0.8}Ga_{0.2}As_{0.44}P_{0.56} disks or rhombuses were prepared on InP pillars, coated in situ with a 5 nm-thick silica layer, and then coated with gold via evaporation from the top. FIG. 26 illustrates plasmonic laser particles and intracellular lasing. Inset (a) shows a schematic of the fabrication. Electron microscopy revealed a conformal gold coating of 80-100 nm thickness, found exclusively on one side (image (b)), with a 5 nm thick silica insulating layer between the semiconductor and gold (image (c). Image (d) shows 580-nm sized samples. Graph (e) shows output spectra of 31 LPs in water of a wide wavelength range (780-920 nm) with pumping at ~20 pJ/μm² per pulse. The single-mode tuning range extends up to 150 nm and can be expanded using different III-V compositions. Narrowband lasing was also observed from LPs with a thinner gold thickness of 15 nm, allowing optical pumping through the gold. Graph (f) is a FDTD simulation of the lasing mode in water. Image (g) shows Hela cells (expressing green fluorescent protein) tagged with LPs (circles). Graph (h) shows the measured spectrum of an intracellular metal-semiconductor laser.

Unlike the earlier substrate-based devices, gold-InGaAsP particles with half-wavelength sizes did not reach the lasing threshold. The smallest LP batch exhibiting lasing in air had a size of 580 nm (FIG. 26, image (d)), corresponding to a mode order of 3. Although lower-order lasing could be achievable with improved gold quality, this size is smaller than the emission wavelength and 2-3 times smaller than the sizes of comparative non-gold-coated InGaAsP LPs. Their emission linewidths were under 4 nm, indicating linewidth Q factors of over 250, suitable for spectral multiplexing and barcoding. For biocompatibility LPs were functionalized with polyethyleneimine coating. Following incubation with Hela cells, polymer-coated LPs were internalized into the cytoplasm (image (g)). Upon optical pumping, these intracellular lasers emitted emission with a linewidth of 4 nm (graph (h)). The excitation energy of several picojoules per pump pulse with peak powers less than 1 mW is acceptable for biological applications, where the pump beam can be rapidly scanned across cells in imaging or in flow cytometry. No detrimental effects of LPs on cell viability were observed.

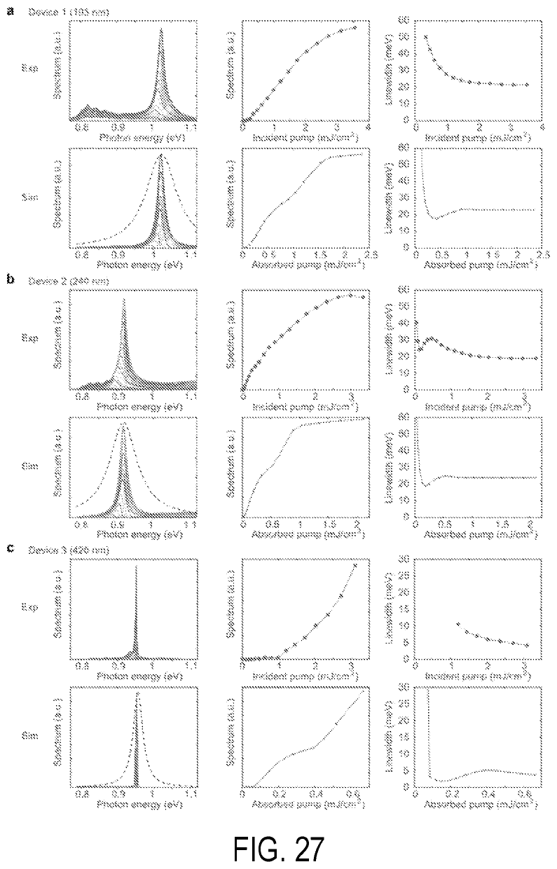

FIG. 27 illustrates laser simulation and experimental results. Graph (a) shows results for a first half-wave device (semiconductor volume: 183×183×130 nm³; graph (b) shows results for a second half-wave device (225×225×130 nm³), and graph (c) shows results for a one-wave device (400×400×130 nm³).

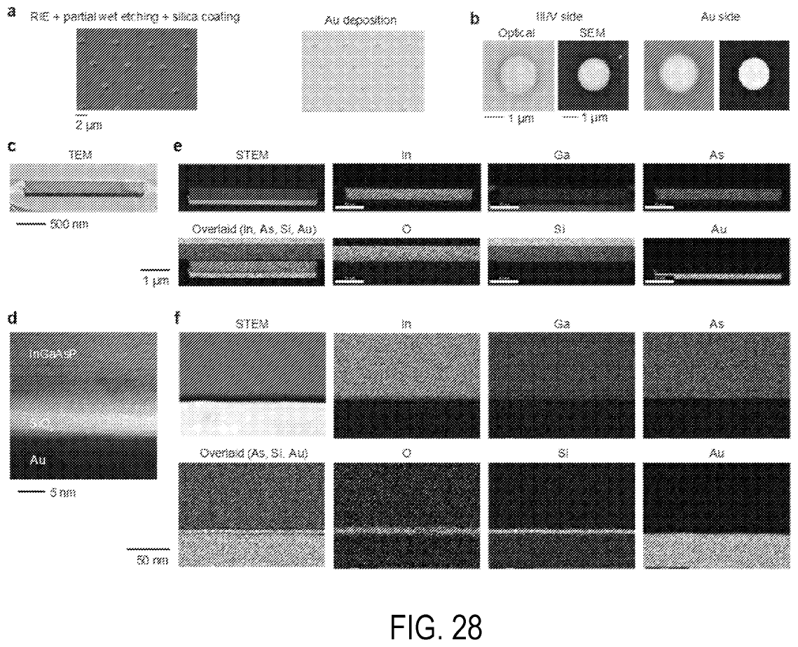

FIG. 28 shows the structure of metal-semiconductor particles. Image (a) is schematic and SEM images of disk-on-pillar array following SiO₂ coating and gold deposition. Image (b) is bright-field and SEM images of plasmonic laser particles drop casted on a silica-coated silicon substrate, presenting both the III/V side (left) and the Au side (right). Image (c) is a TEM image of a cross-section of a sample, prepared by using focused ion-beam (FIB) etching. The image reveals the InGaAsP layer with a thickness of ~290 nm, 5-7 nm thick SiO₂ layer, and ~80-nm thick gold layer. Image (d) is a higher magnification view of the cross section. Images (e) and (f) show STEM images and elemental maps. The samples analyzed in images (c)-(f) were prepared by placing the InGaAsP side on a silica-coated silicon substrate and deposited Ga on top of the Au side of the particles. The samples were then placed up-side down on a TEM grid.

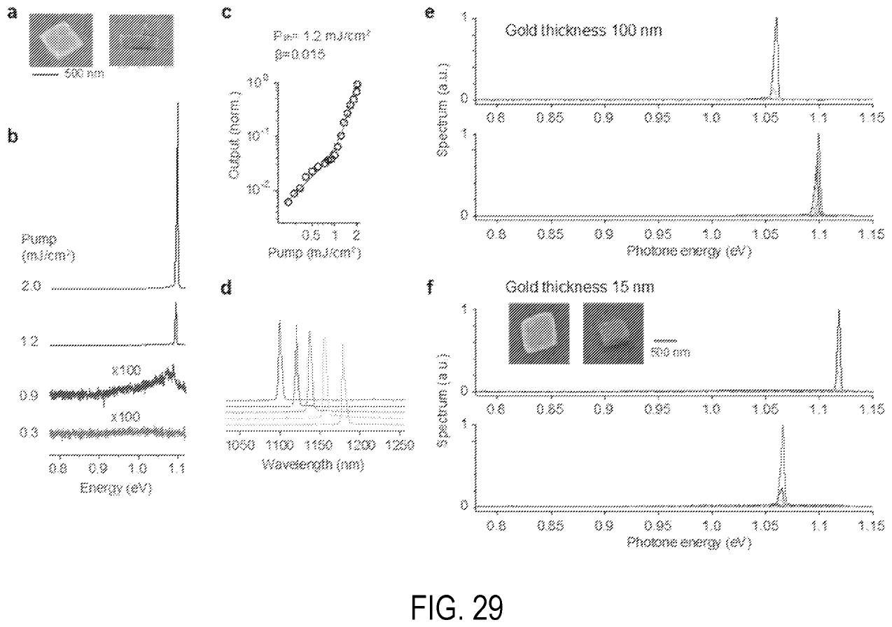

FIG. 29 shows emission spectra of isolated plasmonic LPs. Image (a) shows SEM images of samples with a gold thickness of 100 nm and a side length of 580 nm. Graph (b) presents emission spectra at varying pump fluences. Graph (c) shows light-in-light-out curves measured (circles) along with a theoretical fit (red curve). Graph (d) shows output spectra of 4 LPs. Graph (e) shows the evolution of output spectra of two LPs at pump fluences varying from 0.1 to 4 mJ/cm². The Q factor of the fourth order longitudinal mode in these devices is estimated to be 42. Graph (f) shows LPs made with a gold thickness of 15 nm, and presents spectra of two samples. The inset is SEM images of samples with gold layers facing up. The estimated Q factor of the fourth order mode in these devices is 30.

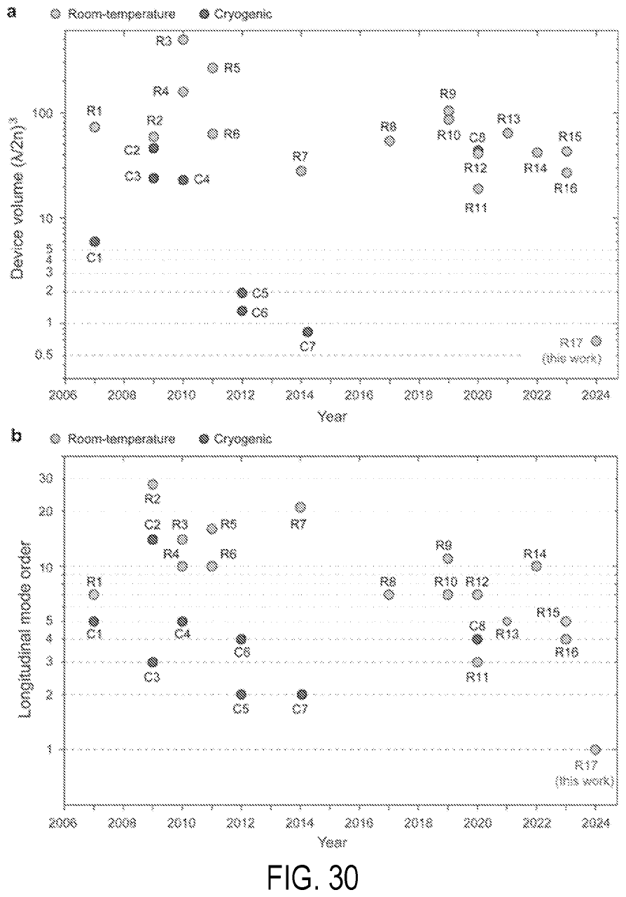

FIG. 30 presents a comparison between systems in accordance with the present disclosure and comparative examples. Device volume is shown at top, and the longest dimension at bottom, of single particle and micro- and nano-lasers operating at room temperature (cyan circles) and cryogenic temperature (pink circles).

This section demonstrates lasers operated in fundamental oscillation frequencies by harnessing the half-wave plasmonic mode. This results in smaller device sizes compared to previous higher-order devices, even surpassing those operating at cryogenic temperatures (see FIG. 30). The miniaturization recipe may prove useful to develop high-density light source arrays for light imaging detection and ranging (LiDAR), laser display, photon computing, and on-chip communications. It is anticipated that proportionally smaller devices could be realized at shorter wavelengths down to 800 nm using other III-V gain media, such as InP and GaAs. The substitution of gold with silver may lead to even narrower devices. The metal-semiconductor design has enabled the production of higher-order mode plasmonic laser particles capable of emitting narrowband light across a broad spectral range. These cell-barcoding nanolasers may be used in various applications including large-scale multiplexed imaging, single-cell analysis, and plasmonic sensing.

### Conformal Metal Coating on Perovskite Microcrystals for Intercellular Plasmonic Lasing

Lead halide perovskites are candidate materials for lasers due to their high gain, excellent solution-based processibility, and broad wavelength tunability. However, their environmental sensitivity poses an obstacle for practical use. This section describes the issue of enhancing photostability in perovskite-based laser particles to improve their performance in aqueous and biological settings. Here the development of gold-coated CsPbBr₃ microparticles that achieve stable lasing in air and enable intracellular and tissue lasing is demonstrated. These particles produce output spectra featuring single peaks with sub-nanometer linewidths, generated through plasmonic hybrid modes of the metal-perovskite core-shell particles. Silver-coated CsPbBr₃ laser particles are also demonstrated. This section paves the way for leveraging the perovskite's distinctive qualities for biomedical applications.

Micro- and nanocrystals of lead halide perovskites (LHP), such as CsPbBr₃ and CH₃NH₃PbBr₃, have received significant for their application in light emitting diodes and photovoltaic devices. Characterized by their low-cost solution-based fabrication process and excellent optoelectronic performance, LHPs offer a high optical gain, making them suitable for the development of miniaturized lasers. The capability for stoichiometry-dependent bandgap tunability presents LHPs as candidates for full-color displays and multicolor bio-imaging across a broad spectrum. Among these, CsPbBr₃ is a laser material candidate due to its high gain in the 520-545 nm range. This effectively addresses the so-called “Green Gap,” a shortage of appropriate III-V or II-VI semiconductor materials in this region.

The development of substrate-free, stand-alone micro and nano-lasers (LPs) as set forth above provides for the introduction of tools in the biomedical sciences, such as cell barcoding. LPs crafted from near-infrared III-V semiconductors have facilitated the tracking of individual cells during time-lapse imaging and multi-pass flow cytometry. However, LHP materials have, according to comparative examples, been deemed unsuitable for biological applications due to their intrinsic water solubility, which leads to rapid degradation in aqueous environments.

In the comparative examples, various coating strategies have been developed to enhance the lifetime of LHP devices, categorized into three main approaches: (i) the physical deposition of protective layers, (ii) the creation of oxide or semiconductor shells, and (iii) encapsulation with polymer or lipid shells. None of these techniques are suitable for LHP laser particles intended for cellular applications. Physical deposition methods prove effective for devices on substrates, where a 50-nm thick Al₂O₃ layer applied to CsPbBr₃ microplates on glass substrates enabled the maintenance of laser functionality in water for a month. Similarly, LHP devices physically sandwiched between 300-μm thick silica substrates demonstrated continuous operation in water for 20 days. However, applying physical deposition to substrate-free particles presents significant challenges.

Oxide and semiconductor shells can enhance the stability of LHP nanocrystals. For instance, Cs₄PbBr₆ shells, formed via a water-triggered transformation of CsPbBr₃, can protect the CsPbBr₃ core. Yet, this method proves inapplicable to CsPbBr₃ microparticles due to low optical gain of nanocrystals. Furthermore, LHP nanoparticles coated with SiO₂, ZrO₂, TiO₂, and CdS have shown a tendency to lose their fluorescence quantum yield due to adverse synthesis conditions involving polar precursors, hydrolytic byproducts, high temperature calcification (at 300° C.), and interfacial charge transfer.

This section introduces an approach for safeguarding LHP microcrystals using noble metals. The method utilizes an initial layer of pNE to capture metal ions. These ions are then transformed into gold films through the application of reducing agents, culminating in a conformal, optically thin layer of gold or silver that envelops the insulated surfaces of CsPbBr₃ particles. This noble metal coating does more than just serve a protective function; it also significantly enhances optical gain through plasmonic interactions. This development has led to gold-coated CsPbBr₃ microparticles retaining single-mode lasing functionality within live biological cells on the order of of hours. Moreover, the metal surface provides a means for the functionalization of particles with a variety of biomaterials, paving the way for advanced applications in biophotonics and beyond.

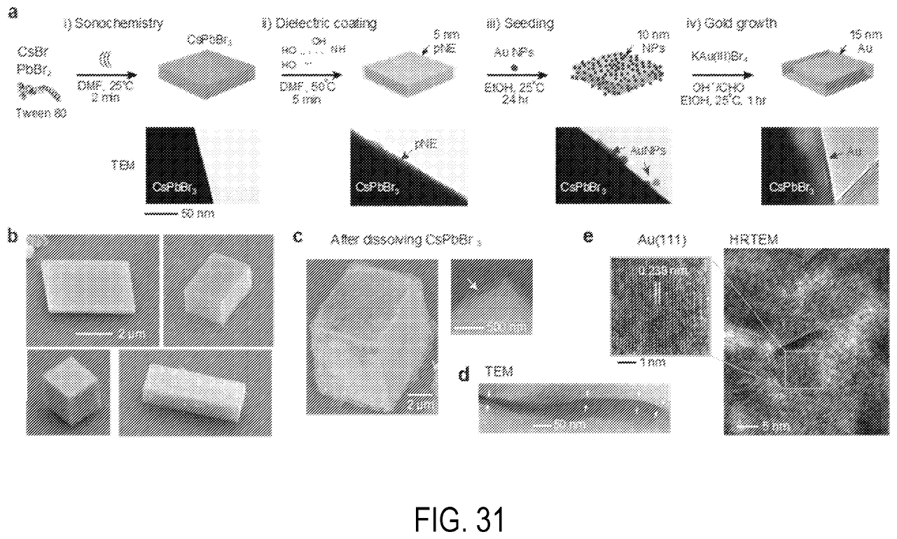

The coating may be provided in four steps, as illustrated in FIG. 31: (i) sonochemical synthesis of all inorganic CsPbBr₃ microcrystals, (ii) application of a pNE dielectric coating in a super-saturated CsPbBr₃ solution, (iii) seeding of gold nanoparticle, and (iv) growth of a thin gold film. TEM captured the stepwise evolution of the CsPbBr₃ particle surface, illustrated bot schematically and in TEM images in row (a) of FIG. 31. Image (b) presents SEM images showcasing gold-coated CsPbBr₃ particles with various aspect ratios. Image (c) presents SEM images displaying the gold/pNE coating approximately 20 nm in thickness on core-shell particles, illustrating conditions of (left) complete and (right) partial dissolution of the CsPbBr₃ core. Image (d) presents a TEM image depicting the 5 nm-thick pNE coating layer. Image (e) shows a high-resolution TEM image of the gold coating layer, exhibiting polycrystalline domains. The inset highlights a region showing the characteristic (111) plane of gold 0.238 nm fringe spacing.

Initially, sonochemistry facilitated the crystallization of orthorhombic CsPbBr₃ microcrystals within a polar aprotic N,N-dimethylformamide (DMF) solution laden with precursors at their saturated point. The addition of a nonionic surfactant, Tween 80, aids in modulating the aspect ratio of CsPbBr₃ microcrystals towards plate-like configurations. Despite the general susceptibility of CsPbBr₃ to polar solvents, the saturated DMF solution stabilized the particles, enabling subsequent surface coating with self-polymerizable norepinephrine without disturbing the saturation conditions.

A conformal pNE coating, approximately 5 nm thick, was then applied, providing organic functional groups for the attachment of 10 nm-sized gold nanoparticles used in seeding. Without pNE coating, gold seeds may attach to the bare surface of CsPbBr₃ particles but fail to be transformed to a conformal gold film. The pNE layer also played a role, acting an insulating gap that prevented charge carrier quenching during laser operation. Gold (III) ions, supplied by KAuBr₄, facilitated this process while avoiding undesirable anion exchange of the CsPbBr₃ perovskite. The final step involved the reduction of gold ions through the electrocatalytic oxidation of ethanol with formaldehyde in alkaline conditions, producing a conformal polycrystalline gold film atop the pNE layer. The use of larger gold nanoparticles resulted in increased metal surface roughness. Increasing the concentration of formaldehyde and NaOH increased the gold thickness. The target thickness of the gold coating was approximately 15 nm, selected to permit optical pumping and laser light emission through the metal layer.

SEM analysis of the resulting gold coated CsPbBr₃ microparticles revealed excellent structural integrity with no noticeable damage (image (b)). These particles retained their structural integrity in water for 1-2 hours before the CsPbBr₃ cores dissolved after extended water exposure for longer than a few hours, leaving behind the metal layer structure (image (c)). This finding indicates an order-of-magnitude improvement in lifetime in water compared to previous pNE-only coated CsPbBr₃ microparticles. Further characterizations after dissolution revealed the combined gold/pNE layer to be about 20 nm thick, with the gold layer itself measuring approximately 15 nm, as the pNE coating was initially 5 nm (image (d). High-resolution TEM images confirmed the polycrystalline nature of the gold film (image (e)), with lattice fringe patterns indicative of the gold (111) plane, measuring a periodicity of 2.38 Å.

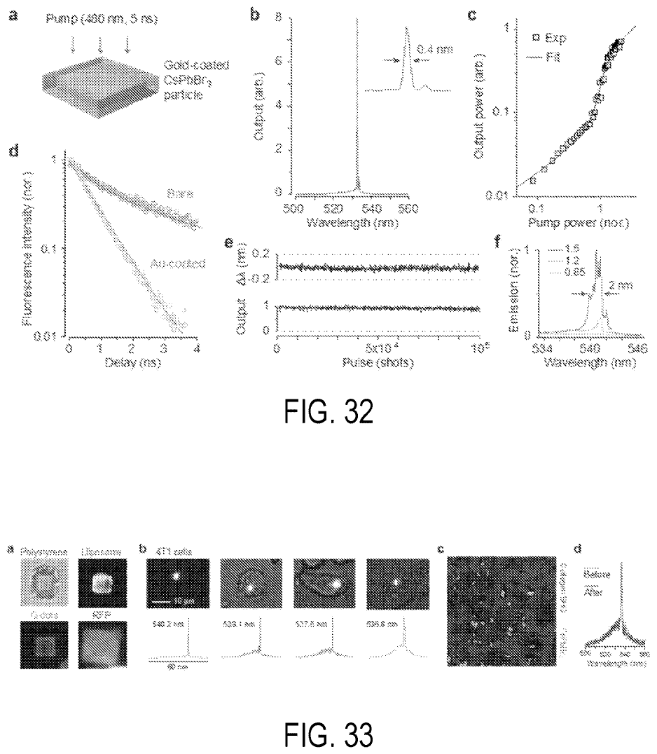

The lasing characteristics of gold-coated CsPbBr₃ particles were measured under ambient room conditions using a custom-built microscope setup, which included a grating based spectrometer with a spectral resolution of 0.2 nm. FIG. 32 illustrates the optical characteristics of the particles. Image (a) is a schematic depicting the process of optical pumping. Graph (b) shows the emission spectrum obtained from a particle sized 2 μm under a pump fluence of 1.2 mJ/cm². The inset shows a detailed zoom of the spectrum. Graph (c) presents measured output power (squares) and a theoretical fitting curve. Graph (d) shows fluorescence decay curves for both gold-coated and uncoated particles (four samples each, sized ~1.8 μm by 1.8 μm by 0.25 μm). Curves are fitted using a double-exponential model. Graphs (e) show the stability of the lasing peak wavelength (top) and intensity (bottom) across 10,000 pumping pulses at a fluence of 1.5 mJ/cm², with plotted traces representing the average from eight samples. Graph (f) includes spectra illustrating random lasing of a particle not coated with pNE but attached to gold seed nanoparticles, observed at three different pump levels: 0.85, 1.2, and 1.5 mJ/cm².

The excitation source consisted of nanosecond pulses from an optical parametric oscillator, tuned to 480 nm. A representative emission spectrum from a gold-coated particle, measuring 2 μm in side-length and 0.2 μm in height, dispersed on a thermal oxide silicon substrate, shown in graph (b). This was obtained at a pump fluence of 1.2 mJ/cm², above a lasing threshold at 0.8 mJ/cm², or 1.6 mW/μm² in peak power, showing a single-mode peak with a linewidth of 0.4 nm and a minor sidelobe. Notably, the low fluorescence background was significantly lower than that usually seen in similar-sized, non-gold-coated CsPbBr₃ particles. The light-in-light-out curve, shown in graph (c), exhibits a characteristic nonlinear increase at the threshold, marked by a kink parameter of 0.04. This parameter is indicative of the product of the spontaneous emission factor (B) and the effective quantum yield during laser oscillation.

Time-resolved photoluminescence spectroscopy demonstrated a significant reduction in the fluorescence decay times of gold-coated CsPbBr₃ particles compared to their uncoated counterparts (graph (d)). Furthermore, FDTD simulations identified plasmonic modes within gold-coated particle models, characterized by a quality factor of 123 and a Purcell factor of 4. The observed decrease in the radiative emission lifetime to 22.5 ns 123 ns in uncoated samples can be primarily attributed to the Purcell effect enhancing the spontaneous emission rate. The Purcell effect also increases the stimulated emission rate during laser oscillation.

Continuous optical pumping at 20 Hz for 500 seconds (equating to 10,000 pump pulses) revealed no significant shift in the emission wavelengths of gold-coated particles, within a resolution of 0.02 nm (graph (e)). However, a slight reduction in output intensity, ranging from 5 to 10%, was observed, suggesting a degree of photo-induced aging during the active operation. Notably, the fluctuations in both lasing peak wavelength and intensity from pulse to pulse were substantially lower, by a factor of 2 to 3, compared to those seen in uncoated particles. This enhanced stability may be due to diminished charge accumulation at the heterojunction interface and lesser exposure to atmospheric oxygen.

A subset of exploratory samples that were fabricated without the pNE coating step demonstrated the ability to produce lasing with relatively broad, multi-peak spectra (graph (e)). This output characteristics is indicative of plasmonic scattering-assisted random lasing phenomena. Optical imaging of these particular particles confirmed the presence of numerous discrete gold seed nanoparticles on the CsPbBr₃ surface.

The improved stability of the gold-coated CsPbBr₃ particles in aqueous environments, coupled with their gold surfaces, facilitated versatile functionalization through various physical and chemical methods. These methods enable the attachment of diverse materials, including polystyrene, liposomes, quantum dots, and fluorescent proteins. FIG. 33 illustrates the functionalization and biological application of such particles. Image (a) shows fluorescence microscopy images showcasing gold-coated CsPbBr₃ particles (emitting green fluorescence) interfaced with various materials, including polystyrene (appearing gray), dye-conjugated liposomes (yellow), CdS/CdSe quantum dots (orange), and red fluorescent proteins (red). Image (b) (top) shows bright-field images of four live 4T1 cells with gold-coated CsPbBr₃ particles (visible as bright spots) with their cytoplasm, under optical excitation, and (bottom) shows emission spectra from these cells. Image (c) is a two-photon excited fluorescence microscopy image of CsPbBr₃ particles (green) injected into porcine sclera tissue. Red areas are second-harmonic generation signals from collagen fibers. Graph (d) is a single-shot emission spectra of a gold-coated CsPbBr₃ particle embedded in the tissue, before and after two-photon excitation microscopy, demonstrating stability.

For instance, sulfur (—SH) groups present on gold surfaces can form covalent bonds with amine (—NH₂) groups through a simple one-step mixing reaction in water. This approach was utilized to attach DsRed fluorescent proteins and CdSe quantum dots to the particles. Furthermore, incorporating the particles into large liposomes of DIR dye-labeled, 1,2-dioleoyl-sn-glycero-3-phosphoethanolamine (DOPE) and 1,2-dioleoyl-3-trimethylammonium-propane (DOTAP) resulted in their liposomal encapsulation, enhancing their delivery into cells in vitro.

Comparative attempts to observe lasing with liposome-encapsulated, pNE-only coated CsPbBr₃ particles delivered into cells were unsuccessful. However, the augmented stability afforded by the gold coating enabled intracellular lasing within live 4T1 breast cancer cells (FIG. 33 image (b)). The average threshold fluence for inducing lasing in intracellular particles was found to be 0.83 mJ/cm². The estimated lifetime of gold-coated particles within the cytoplasm extended to approximately two hours, likely due to the formation of a protective protein corona around the particle surfaces, slightly improving their lifespan compared to their stability in water. When injected into hydrated porcine sclera tissue ex vivo, the gold-coated CsPbBr₃ particles demonstrated their ability to lase, enduring the femtosecond laser pulses (~150 fs, 100 pJ, 80 MHz, 920 nm) employed in two-photon microscopy without degradation (FIG. 33, (c) and (d)). These results demonstrate the potential of these gold-coated LPs for biological applications.

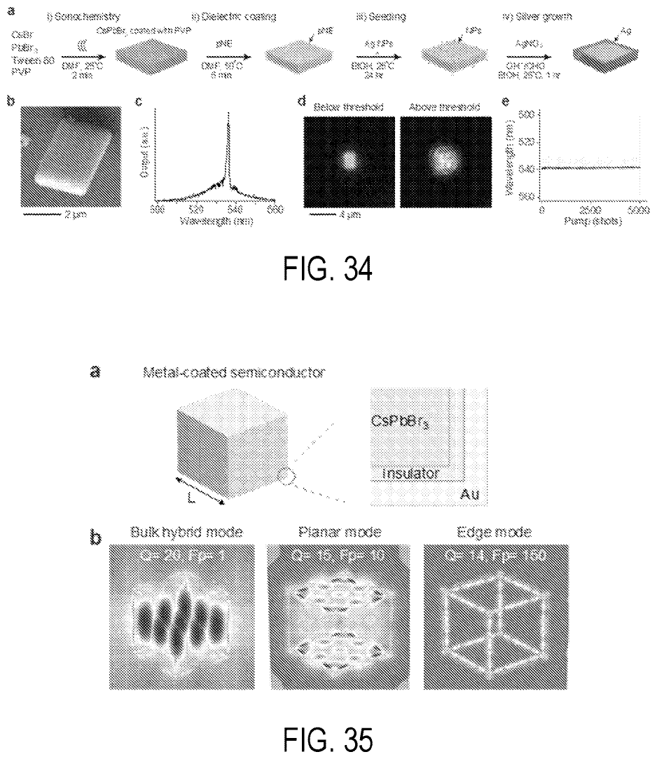

In addition to gold, silver may be utilized. The approach to achieving conformal silver coating involves the use of 10 nm-sized silver seed nanoparticles and silver nitrate (AgNO₃) as the source of Ag (I) ions. FIG. 34 illustrates the process schematically. Row (a) provides a schematic illustrating the sequence of steps for applying a silver coating. The application of an initial polyvinylpyrrolidone (PVP) layer as a dielectric insulator is critical for maintaining stable photoluminescence. Image (b) is a SEM image showcasing a silver-coated CsPbBr₃ particle. Graph (c) shows emission spectrum from a 2.4-μm-sized, silver-coated particle at a pump fluence of 1.5 mJ/cm². Image (d) presents far-field emission profiles illustrating the transition below and above the lasing threshold. Graph (e) is a time-lapse trace of emission spectra showing the stability of the laser peak wavelength and intensity with continuous pumping at 1.5 mJ/cm².

One distinction from the previously described gold coating methodology is the incorporation of a nonionic polymeric surfactant, specifically PVP, during the sonochemical synthesis of the CsPbBr₃ particles. This surfactant creates thin encapsulating layer, a few nanometers thick, around the CsPbBr₃ cores, acting as a dielectric energy barrier. This barrier in effective in preventing the undesirable transport and quenching of photo-induced charges between the CsPbBr₃ cores and the surrounding pNE and silver layers during laser oscillation. The absence of PVP leads to rapid degradation of the silver coated particles upon photoexcitation. This degradation is attributed to the ability of Ag⁺ ions to penetrate the pNE layer and directly interact with the catechol groups of pNE, which in turn causes quenching of the photo-induced charges from the CsPbBr₃ core. Notably, the gold coating process does not necessitate a PVP barrier because Au³⁺ ions tend to coordinate with the outer surface of the pNE layer rather than penetrating it.

TEM images visualized the high surface quality of the silver-coated CsPbBr₃ particles, showing no significant damage (FIG. 34 image (b)). Upon optical pumping with fluences exceeding 1 mJ/cm², we observed single-peak laser emissions (graph (c)). The far-field emission profiles, particularly above the lasing threshold, displayed symmetric interference patterns indicative of narrowband laser emissions (image (d)). Moreover, time-lapse recordings of the output spectra confirmed the stability of the silver-coated particles under continuous pumping (graph (e)). Among various polymers evaluated, including polyhedral oligomeric silsesquioxane (POSS), PVP was found to provide the greatest stability for the silver-coated CsPbBr₃ particles. While stable in air, however, silver-coated particles immersed in water survived only briefly, less than 10 minutes, before they lose photoluminescence functionality. Further modification of charge insulating barriers may extend the lifespan.

This section thus developed noble metal-perovskite core-shell laser particles (LPs) employing entirely solution-based chemistry methods. The resulting particles, coated with either gold or silver, demonstrated stable lasing performance in air. In particular, the gold-coated particles achieved intracellular lasing with single narrowband peaks. Numerical FDTD simulations have led to the conclusion that the lasing modes observed are plasmonic or, more accurately, plasmonic-photonic hybrid modes.

### Plasmonic Edge Modes in Metal-Coated Nanolasers

The substrate-free plasmonic lasers described above enable distinctive plasmonic modes highly localized along the particle's edges, exhibiting a Purcell factor exceeding 100 and a Q-factor ranging from 10 to 20. Utilizing submicron CsPbBr₃ perovskite cores with a conformal 15-nm thick gold shell, single-mode plasmonic lasing may be achieved. The lasing produces, in an example, a linewidth of 0.6 nm at 538 nm, achieved with 480-nm nanosecond pumping at 10 pJ/μm². The lasing edge modes are stable against external perturbations. These results indicate the potential of these plasmonic laser particles for applications that require narrowband and robust emission characteristics.

Plasmonic edge modes, localized along the 90-deg folded edges of the metal shell, have advantage over traditional planar or bulk plasmonic, leading to lasing at lower thresholds. These edge modes are similar to channel plasmon polaritons (CPP) studied in plasmonic waveguides. Lasing of a CPP mode in an AlGaAs nanowire placed on a gold V-groove has been demonstrated. Simulations show that the edge modes in gold-coated LPs are especially effective near the plasmonic resonance frequency.

FIG. 35 illustrates the schematic of a semiconductor structure coated with metal (e.g., a perovskite semiconductor particle encapsulated by an insulator layer, followed by an outer gold shell). When the gold shell's thickness is approximately equal to its skin depth or less, the semiconductor gain medium can be excited by external optical pumping, allowing the amplification of SPP waves in the gold-semiconductor interface. This section concentrates on the CsPbBr₃ gain medium, which exhibits a gain peak at approximately 540 nm. This wavelength closely matches the SPP resonance of gold, considering the perovskite's refractive index (n) of 2.3. FIG. 35 image (b) shows three distinct types of modes supported by the structure, identified through FDTD simulations of a perovskite cube with a side length (L) of 400 nm and a gold thickness of 15 nm, observed through the perovskite's gain range between 520-545 nm. While all modes are, strictly speaking, hybrid modes, the planar and edge plasmonic modes are particularly confined to the side walls and edges, respectively. The edge mode is characterized by opposing charges on the facing gold layers, similar to CPP waves in metal bracket waveguides and short-range SPP waves in metal-insulator-metal waveguides. The Q factor of the edge mode is comparable to that of the extended photon-like and planar plasmonic modes. However, it offers the highest Purcell factor (Fₚ).

To illustrate this, a figure-of-merit (FOM) may be used, defined by the product of these two factors for evaluating the performance of nanoscale lasers, where radiative loss is prevalent. According to a simple laser theory, this FOM is inversely proportional to the threshold carrier density (ρₜₕ) and may be expressed as FOM=Q·Fₚ≈ωₒ/ρₜₕV. In this expression, ω₀ represents the mode frequency and V denotes the effective volume of the gain medium. The FOM of the edge mode is significantly higher than for the bulk mode and for the planar mode, highlighting its potential for lasing at lower thresholds.

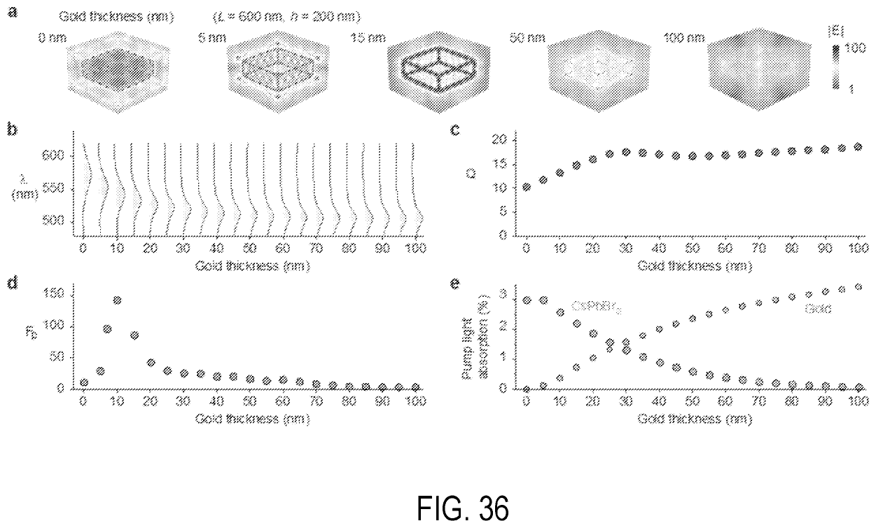

Using FDTD, the impact of the gold layer thickness on the properties of various modes, including the electric-field profile, Mie scattering resonance spectrum, Q-factor, Purcell factor, and optical transmission, across a range from zero (uncoated) to 100 nm in thickness, is examined. At the interface with perovskite, the theoretical skin depth for semi-infinite gold is 12 nm, and it is 17 nm at the air-facing interface. FIG. 36 shows the impact of the gold-shell thickness, presenting shows simulation results for a CsPbBr₃ core with dimensions of 600 nm by 200 nm. Image (a) shows the electrical field profiles (|E| on a log scalle) for particles with different gold thicknesses. Graph (b) shows Mie-scattering profiles. Graph (c) is the Q factor. Graph (d) presents the Purcell factor. Graph (e) shows the percentage absorption of 480-nm pump energy within the perovskite core and the gold shell. Notably, field localization at the edges is most pronounced with a gold thickness of 15 nm (see image (a)). The resonance peak wavelength, starting at 520 nm for optically thick gold, undergoes a red-shift for gold layers thinner than approximately 25 nm, moving toward 580 nm at nearly zero gold thickness, consistent with the Goos-Hanchen effect (graph (b)). The Q factor experiences a decrease 18 for thick gold to 10 at zero thickness (graph (c)). The Purcell factor peaks at approximately 200 for gold layers around 10 nm thick but drops sharply for thinner layers 36 (graph (d)). At a pumping wavelength of 480 nm, the absorption by the perovskite core starts at 3% without metal and diminishes exponentially with a skin depth of 25 nm (graph (e)). For smaller particles maintaining a gold thickness of 15 nm, the edge modes, particularly along the particles' longest dimension, preserve Q≈20 and Fₚ>50, extending down to sizes nearing the diffraction limit of 117 nm. Mie scattering simulations reveal that the edge mode emerges only when the side length reaches 580 nm, at which point the resonance wavelength exceeds the plasmonic wavelength (graph (e)).

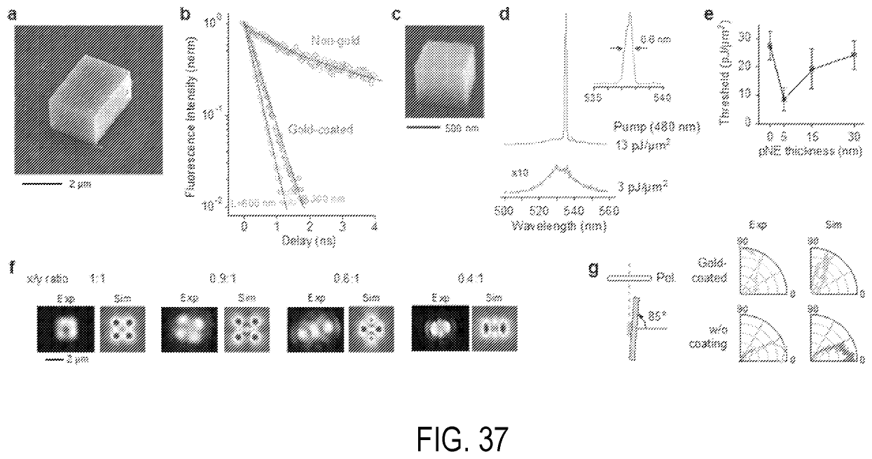

In an experimental demonstration, CsPbBr₃ particles were synthesized using a sonochemistry method, with poly-norepinephrine (pNE) layer serving as a dielectric insulating layer before adding a gold-shell coating. This coating was achieved by reducing the Au (III) ions with gold nanoparticle seeds. The size of the perovskite crystals was controlled by adjusting the sonochemistry parameters. A SEM image shown in FIG. 37 reveals a cuboidal-shaped particle, with the pNE and gold layers aimed to be approximately 5 nm and 15 nm thick, respectively. Compared to non-metal-coated samples, which exhibited a photoluminescence decay time of ~150 ns, the gold-coated samples demonstrated significantly accelerated decays (FIG. 37 graph (b)), with a lifetime of 0.83 ns corresponding to a Purcell factor of 180. The fluorescence quantum yield of uncoated CsPbBr₃ microcrystals was recorded at 1.5% due to defects created during the sonochemistry process. The Purcell-enhanced emission can increase the quantum yield to nearly 100% during laser oscillation.

FIG. 37 illustrates properties of the gold-coated CsPbBr₃ particle. Image (a) is a SEM image of the particle. Graph (b) shows time-resolved resolved photoluminescence decay of gold-coated particles versus non-gold coated particles. Lines show double-exponential fits. Image (c) shows a submicron lasing sample. Graph (d) shows output emission spectra from the device in image (c) pumped by 480-nm nanosecond light. Graph (e) is the measured threshold pump fluence for samples with different pNE layer thicknesses. Error bars indicate the standard deviation of five samples per group. Image (f) shows far-field intensity profiles from four samples with different aspect ratios, compared to FDTD simulation results. Image (g) is a schematic of polarization measurement setup and measured vs. simulated output polarization states of coated and uncoated samples.

For lasing tests, the samples were dispersed on thermal-oxide silicon substrates and exposed to 5-ns pump pulses at 480 nm wavelength. Emissions were analyzed using a hyperspectral microscope at room temperature. Post-optical measurements involved marking particle locations on the substrate with high-energy 480-nm pulses, followed by SEM imaging to determine particle sizes. FIG. 37 image (c) shows one of the smallest devices measured (680×530×490 nm³; L=620 nm) that showed lasing. Notably, pristine CsPbBr₃ crystals without gold coating did not exhibit lasing. The observed single-mode spectra had a linewidth of 0.6 nm at pump fluences beyond the threshold, which is about 40 times narrower than the below-threshold fluorescence (25 nm). The pump threshold fluences measured from several submicron particles ranged 9±4 pJ/μm². Despite approximately 50% loss of pump light through the gold layer, the absorbed pump energy at threshold was similar to that of uncoated perovskite particles on a flat gold substrate. Graph (e) shows threshold pump fluences for samples with varying pNE thicknesses, identifying 5 nm as the preferred thickness. Without the pNE layer, the pump threshold was higher, possibly due to carrier tunneling.

The far-field intensity patterns observed in the experiments were consistently replicated by the FDTD simulation of edge modes (image (f)). The two-photon excited fluorescence imaging of the samples yielded distinct patterns, markedly different from those of non-metal-coated counterparts. The experimental setup for measuring far-field polarization states is depicted in graph (g). Considering the large lateral-to-height aspect ratio of the particles and their orientation on the mounting substrate, this arrangement is thought to disrupt symmetry and favor lasing mode propagation along the long edges of the particles, parallel to the substrate plane, aligning with simulations that predict electric-field orientations at about a 65-degree angle. In contrast, polarization measurements for uncoated particles showed alignment largely parallel to the substrate plane, aligning with the expected behavior of transverse-electric (TE) whispering gallery modes.

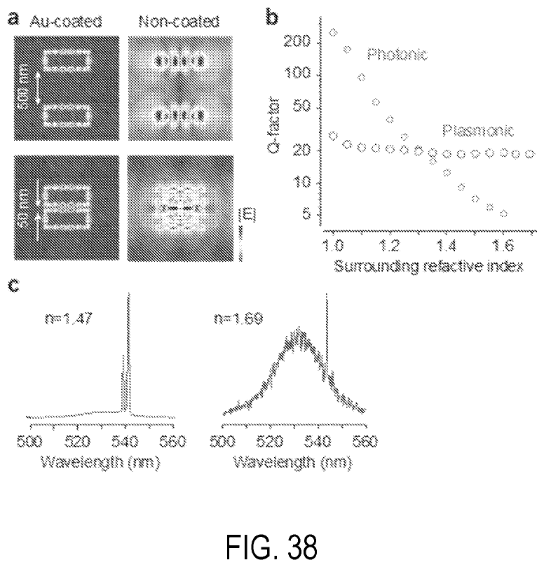

The rapid decay of edge modes outside the metal layer suggest that these lasing modes could maintain stability against external perturbations. FIG. 38 shows the sensitivity of lasing devices to their external environment. Image (a) presents field distributions for the edge modes of two gold-coated particles on the left, and the photonic mode of two uncoated devices on the right, across varying intraparticle distances, and illustrates the effect of proximity on the resonant mode profiles of two particles, as their separation decreases from 550 nm to 50 nm. Graph (b) shows estimated Q-factors of both gold-coated and uncoated particles with a side length of 1 μm when immersed in media of different refractive indices. While the fields in devices without metal coating show strong coupling, the plasmonic LPs remain largely unaffected. The Q-factor of the plasmonic edge mode is nearly constant across different surrounding refractive index. Lasing was achieved with metal-coated LPs in both mineral oil (n=1.47) and poly-phenyl ethers (n=1.69) lipid, as seen by the lasing spectra of graph (c). Conversely, uncoated photonic LPs, despite being large (up to 4 μm) and stable in organic fluids, did not achieve the lasing threshold in environments with a high refractive index.

### Quarter-Wave Plasmonic Laser Particles

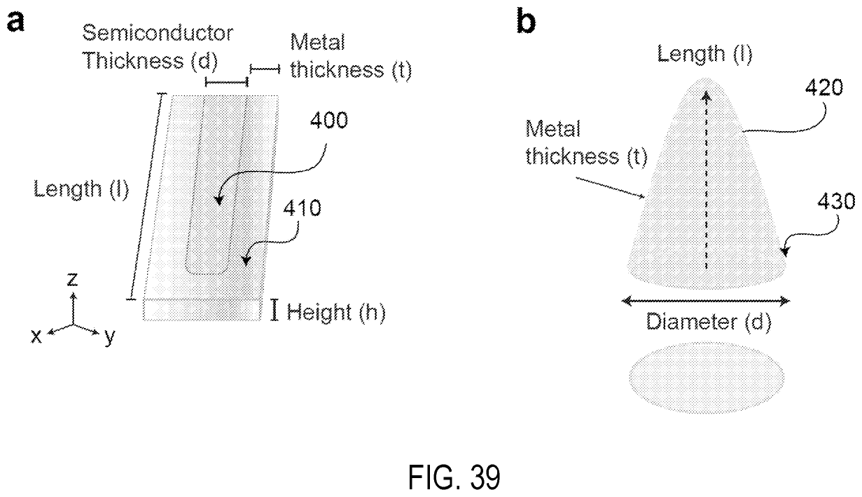

Plasmonic quarter-wave resonances, also known as magnetic dipole plasmonic resonances, in tuning fork or bell-shaped cavities allow for further miniaturization of plasmonic laser particles. These resonances can be achieved by partially coating semiconductor particles with plasmonic metal. FIG. 39 illustrates two representative comparative structures. FIG. 39, view (a) shows a tuning fork-shaped particle, which has a semiconductor gain particle 400 coated with a metal layer 410 with three non-metal-coated sites. FIG. 39, view (b) presents a bell-shaped particle, which has a semiconductor gain particle 420 coated with a metal layer 430 with one non-metal-coated site. The metal coating thickness (t) of tuning fork- or bell-shaped particles ranges from 5 nm to 300 nm. Considering effective optical pumping with penetrating metal coating and maximizing the Purcell effect, the preferred thickness lies between 10 nm to 40 nm. The dielectric layer can be inserted in between a semiconductor gain particle and a metal layer in both cases for preventing carrier quenching. The optical thickness is around 5 nm for effective plasmonic coupling and charge insulation.

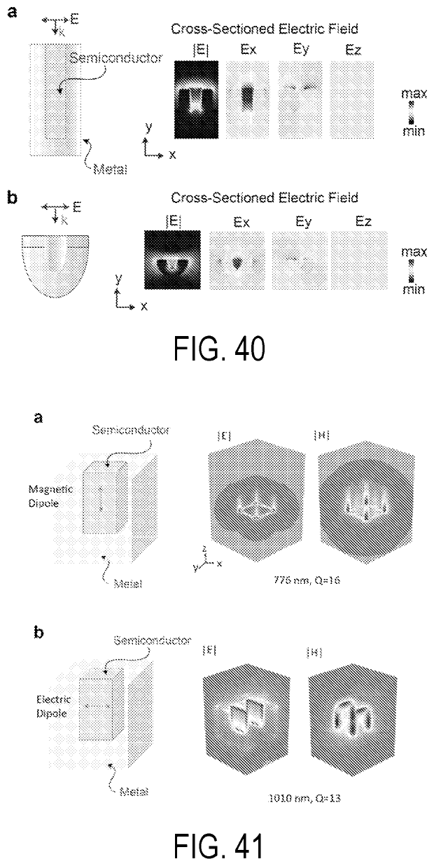

FIG. 40 presents Mie scattering simulations of a tuning fork-shaped semiconductor particle (diameter, 40 nm; refractive index, 3.4) coated with gold (thickness, 20 nm) with two different geometries of rectangular (a) and half-rod (b). The external electric field in the x-y plane illuminates the particle and excites quarter-wave resonances in NIR spectral regime. In the cross-sectioned profile at the center of the particle, strong oscillations were observed in the Ex-field, corresponding to the opposite-signed charge distribution of each arm of the fork.

The results of dipole simulation for a bell-shaped cube semiconductor particle (diameter, 80 nm; refractive index, 3.4) coated with silver (thickness: 30 nm) are depicted in FIG. 41. Images (a) and (b) present the resonance modes excited by magnetic and electric dipoles, respectively. Two resonances with quality factors of 16 and 13 were observed, each exhibiting distinct patterns. The resonant wavelengths were 776 nm and 1010 nm, respectively, with the 1010 nm wavelength indicating the lowest order quarter-wave resonance.

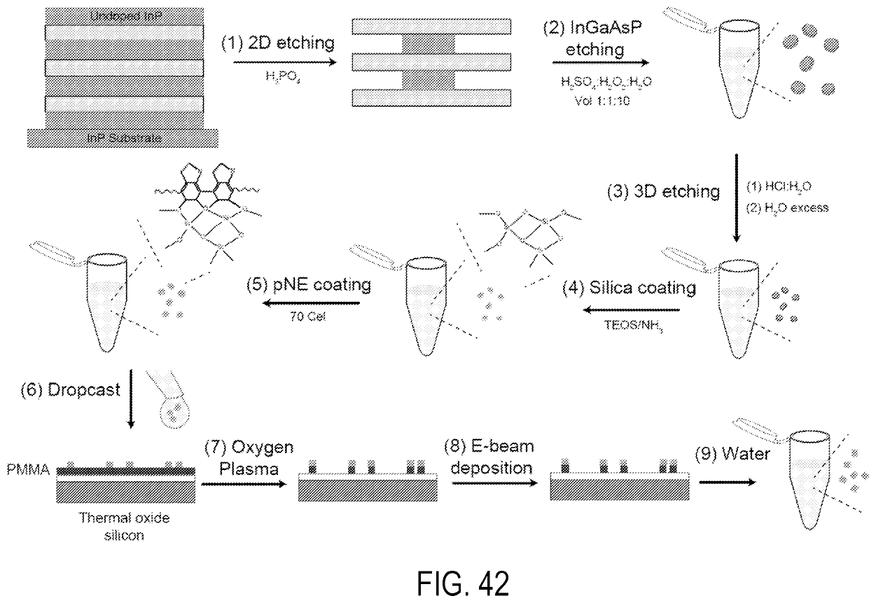

FIG. 42 illustrates the schematic of the particle preparation procedure. Quarter-wave plasmonic laser particles can be prepared using the following procedures. For example, for an InP-based laser, submicron-sized InP core particles are fabricated through top-down lithography and wet chemistry involving the removal of sacrificial layers of InGaAsP using a piranha solution of H₃PO4 acid. The resulting free-standing InP particles are further miniaturized through wet etching using HCl. These prepared particles are then coated with a dielectric material such as silica or polynorepinephrine, approximately 5 nm thick. Next, the particles are placed on a substrate coated with poly(methyl methacrylate) (PMMA), and oxygen plasma etching is employed to remove the PMMA exposed to air, leaving behind PMMA pillars supporting the InP particles upright. The particles on the PMMA pillars are further coated with plasmonic metals such as gold or silver using either electron-beam deposition or wet chemistry involving metal ion reduction or light illumination. After gold or silver coating, the PMMA layer is gently removed using water, ethanol, or acetone to release the quarter-wave plasmonic laser particles into solution. Subsequently, these particles can be further coated with silica to enhance biocompatibility and protect the metal from oxidation.

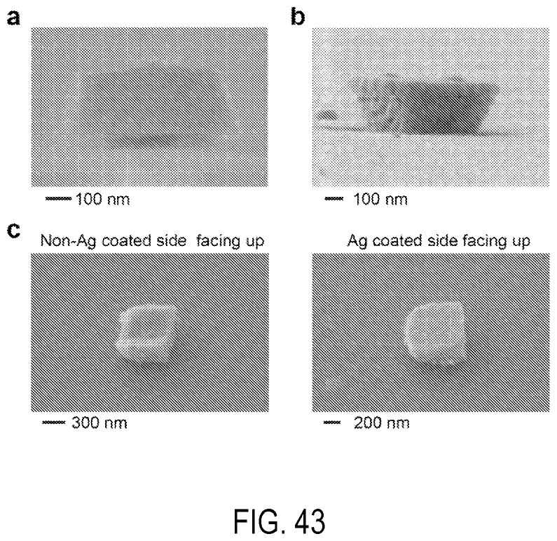

FIG. 43 depicts SEM images of the particle during the fabrication process. Image (a) shows the InP particle situated on the PMMA pillar on the substrate. Image (b) illustrates the particle after electron-beam deposition of silver onto the InP particle on the substrate. Image (c) shows the coated particle released from the substrate by removing the PMMA pillar using water and transferred to the bare silica-coated silicon substrate. The image on the left depicts the non-Ag-coated side facing up, exposing the InP core, while the image on the right shows the Ag-coated side facing up.

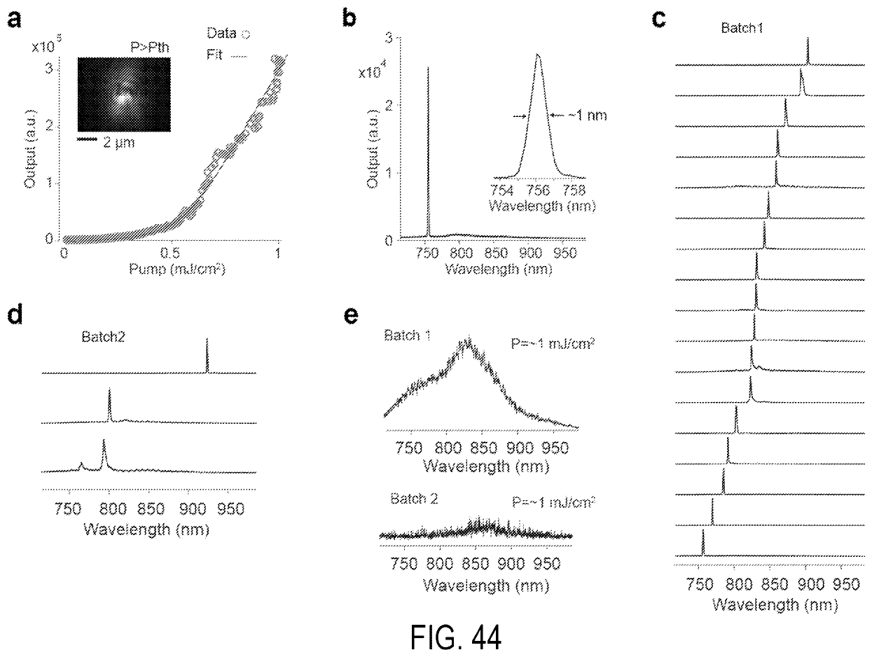

FIG. 44 presents laser experiments on two batches (batch 1: 336 nm±70 nm and batch 2: 129 nm±63 nm) of Ag-coated bell-shaped particles. The particles on the thermal oxide silicon substrate were excited by a 532 nm pump laser with a pulse duration of 5 ns and a repetition rate of 10 kHz. The emission was recorded using an objective lens with 0.45 N.A. and a line-confocal spectrometer for emission spectra recording, along with an EMCCD for wide-field imaging. Nonlinear kink behavior of lasing was observed with a threshold energy of around 0.5 mJ/cm² (FIG. 44, image (a)). The spatial emission pattern above the threshold energy presents an interference pattern, which is a signature of the lasing action (FIG. 44, image (a)). The emission linewidth was recorded as 1 nm when using a grating with a resolution of 0.8 nm (FIG. 44, image (b)). Due to the different sizes of the particles, different emission peak positions were observed within the range of 750 nm to 900 nm (FIG. 43, image (c)). Batch 2 particles also exhibit narrow emission above the threshold energy with a linewidth of 3 nm (FIG. 44, image (d)). This broad linewidth also stems from the low-Q resonance compared to the batch 1 particles. Non-silver-coated particles from both batch 1 and batch 2 on the same substrate did not show lasing action despite near-damaging threshold high pump energy (FIG. 44, image (e)).

Other examples and uses of the disclosed technology will be apparent to those having ordinary skill in the art upon consideration of the specification and practice of the invention disclosed herein. The specification and examples given should be considered exemplary only, and it is contemplated that the appended claims will cover any other such embodiments or modifications as fall within the true scope of the invention.

The Abstract accompanying this specification is provided to enable the United States Patent and Trademark Office and the public generally to determine quickly from a cursory inspection the nature and gist of the technical disclosure and in no way intended for defining, determining, or limiting the present invention or any of its embodiments.

What is claimed is:

1. A laser particle for generating plasmonic stimulated emission, comprising:
a semiconductor particle configured to provide a gain; and
a metal layer disposed on at least one surface of the semiconductor particle, the metal layer configured to provide plasmons,
wherein a size of the laser particle is less than 3 μm along its longest dimension.

2. The laser particle of claim 1, wherein a spectral linewidth of the plasmonic stimulated emission is less than 1/20^{th} of a center wavelength of the plasmonic stimulated emission. The laser particle of claim 1, wherein the size of the laser particle is less than an optical wavelength in air, along its largest dimension.

4. The laser particle of claim 1, wherein a thickness of the metal layer is between 5 nm and 40 nm.

5. The laser particle of claim 1, wherein the laser particle has a discoidal, spherical, or cuboidal shape.

6. The laser particle of claim 1, wherein the metal layer is disposed on all surfaces of the semiconductor particle.

7. The laser particle of claim 1, further comprising an insulator layer, wherein the insulator layer is at least one of disposed between the semiconductor particle and the metal layer, attached to the semiconductor particle or the metal layer, or surrounding an entirety of the semiconductor particle and the metal layer.

8. The laser particle of claim 7, wherein the insulator layer includes at least one of a poly-norepinephrine material, a polyvinylpyrrolidone material, or a silica material.

9. The laser particle of claim 1, wherein the semiconductor particle includes at least one of a III/V semiconductor material, a II/VI semiconductor material, or a perovskite material.

10. The laser particle of claim 9, wherein the semiconductor particle includes InGaAsP.

11. The laser particle of claim 1, wherein the metal layer includes at least one of a noble metal, aluminum, or an alloy.

12. An apparatus for generating plasmonic stimulated emission, comprising:
a laser particle comprising a semiconductor particle and a metal layer disposed on at least one surface of the semiconductor particle;
a pump source configured to provide electromagnetic energy to the laser particle to excite plasmonic modes; and
a photodetector configured to detect the plasmonic stimulated emission.

13. The apparatus of claim 12, wherein a size of the laser particle is less than 3 μm along its longest dimension.

14. The apparatus of claim 12, wherein a thickness of the metal layer is between 5 nm and 40 nm.

15. The apparatus of claim 12, wherein the laser particle has a discoidal, spherical, or cuboidal shape.

16. The apparatus of claim 12, wherein the metal layer is disposed on all surfaces of the semiconductor particle.

17. The apparatus of claim 12, further comprising an insulator layer, wherein the insulator layer is at least one of disposed between the semiconductor particle and the metal layer, attached to the semiconductor particle or the metal layer, or surrounding an entirety of the semiconductor particle and the metal layer.

18. The apparatus of claim 17, wherein the insulator layer includes at least one of a poly-norepinephrine material, a polyvinylpyrrolidone material, or a silica material.

19. The apparatus of claim 12, wherein the semiconductor particle includes at least one of a III/V semiconductor material, a II/VI semiconductor material, or a perovskite material.

20. The apparatus of claim 12, wherein the metal layer includes at least one of a noble metal, aluminum, or an alloy.

21. A method for generating plasmonic stimulated emission, comprising:
providing a laser particle, the laser particle comprising a semiconductor particle and a metal layer disposed on at least one surface of the semiconductor particle;
delivering an electromagnetic energy to the laser particle to excite plasmonic modes; and
detecting the plasmonic stimulated emission.

22. The method of claim 21, wherein a spectral linewidth of the plasmonic stimulated emission is less than 1/20^{th} of a center wavelength of the plasmonic stimulated emission.

23. The method of claim 21, wherein a size of the laser particle is less than an optical wavelength in air, along a largest dimension of the semiconductor particle.
